(19) United States
(12) Patent Application Publication
(10) Pub. No.: US 2025/0311211 A1
(43) Pub. Date: Oct. 2, 2025

(54) STRETCHABLE FLOATING GATE BASED MEMORY TRANSISTOR, MANUFACTURING METHOD THEREOF AND MEMORY DEVICE

(71) Applicant: UNIVERSITY-INDUSTRY COOPERATION GROUP OF KYUNG HEE UNIVERSITY, Yongin-si (KR)

(72) Inventors: Jin Young OH, Anyang-si (KR); Tae Uk NAM, Uiwang-si (KR); Ngoc Thanh Phuong VO, Suwon-si (KR)

(73) Assignee: UNIVERSITY-INDUSTRY COOPERATION GROUP OF KYUNG HEE UNIVERSITY, Yongin-si (KR)

(21) Appl. No.: 19/040,316

(22) Filed: Jan. 29, 2025

(30) Foreign Application Priority Data
Apr. 2, 2024 (KR) 10-2024-0044661

(51) Int. Cl. H10B 41/30

(52) U.S. Cl. CPC H10B 41/30

(57) ABSTRACT

Example embodiments provide a memory transistor, memory device, and method of manufacturing thereof, wherein a stretchable floating gate is formed by thermally evaporating metal nanoparticles onto an elastomer dielectric layer. This structure operates reliably across various environmental conditions such as temperature, humidity, bending, and shock, with no data loss. Moreover, the memory transistor may selectively operate as a flash memory or a WORM (Write Once Read Many) memory.

### CROSS-REFERENCE TO RELATED APPLICATION

This application claims priority from and the benefit of Korean Patent Application No. 10-2024-0044661 filed on Apr. 2, 2024, in the Korean Intellectual Property Office, the disclosure of which is incorporated herein by reference.

### BACKGROUND OF THE DISCLOSURE

### Field of the Disclosure

Example embodiments relate to stretchable memory device technology, and more specifically, to a stretchable floating gate-based memory transistor, its manufacturing method, and a memory device.

Example embodiments are the result of research conducted with the support of the 2023 Gyeonggi-do Regional Research Center project (GRRC_2023) funded by Gyeonggi-do, pursuant to the agreement. (1. Project Number: 20232870, Project Title: [GRRC-Phase 1 Stage 1-Application 3] Research on Hybrid Material-Based Flexible Semiconductor Processes and Device/Packaging Technology (1/3)).

### Description of the Related Art

Electronic skin (e-skin) is an electronic module equipped with various electronic components, designed to mimic the mechanical properties of human skin. This e-skin has evolved into an innovative electronic platform that interacts with biological systems, finding applications in emerging fields such as healthcare, neuroprosthetics, and artificial organs.

While various functions of e-skin, such as stretchable sensors, displays, and electronic circuits, have been developed, research on stretchable memory devices remains in its early stages. The most effective approach to developing stretchable memory devices for e-skin is to use non-volatile field-effect transistors (FETs). Field-effect transistor technology is widely commercialized and proven reliable. Non-volatile FETs offer the advantage of independently controlling vertical gate bias and horizontal source/drain bias, as well as leveraging spatial and temporal effects. Due to these advantages, non-volatile FETs are emerging as a promising architecture for e-skin applications.

Among these, memory FETs with floating gates have advantages such as long-term data retention, low power consumption, high reliability, and high read/write speeds. Memory transistors with floating gates typically use metal or semiconductor materials in an insulating dielectric layer to store charges. Information can be written and read in the form of charges through direct tunneling and Fowler-Nordheim (FN) tunneling effects in write and erase states.

To integrate floating gate memory transistors into e-skin devices, they must possess sufficient stretchability to ensure data retention even under mechanical deformation. However, characteristics such as durability under various environmental conditions-including temperature, humidity, bending, and impact-pose significant challenges in manufacturing flexible and stretchable memory transistors.

### SUMMARY

Example embodiments aim to provide a memory transistor, a memory device, and a method of manufacturing the same, in which a stretchable floating gate is formed by thermally depositing metal nanoparticles onto an elastic dielectric layer. This enables the device to maintain stretchability and operate reliably under various environmental conditions such as temperature, humidity, bending, and impact, without data loss.

Additionally, example embodiments aim to provide a memory transistor, a memory device, and a manufacturing method thereof, which operate as a transistor when only a voltage is applied. When both light and voltage are applied for writing, the device functions as a flash memory, allowing erasure, when the floating gate thickness is 15 to 20 nm, and as a WORM (Write Once Read Many) memory, preventing erasure, when the floating gate thickness is 1 to 10 nm.

An embodiment provides a memory transistor comprising a blocking dielectric layer formed of an elastomer film; a stretchable floating gate layer laminated on an upper surface of the blocking dielectric layer; a tunneling dielectric layer formed of an elastomer film, laminated on the upper surface of the blocking dielectric layer and the stretchable floating gate layer; and a nanoweb semiconductor layer laminated on the upper surface of the tunneling dielectric layer, wherein the stretchable floating gate layer includes metal nanoparticles deposited in particulate form on the tunneling dielectric layer through thermal evaporation, forming a stretchable planar structure.

The blocking dielectric layer can be formed by spin-coating an elastomer solution to a thickness of 750 to 900 nm.

The tunneling dielectric layer can be formed by spin-coating an elastomer solution to a thickness of 25 to 100 nm.

The stretchable floating gate layer can be formed to a thickness of 1 to 30 nm.

The nanoweb semiconductor layer can be formed by mixing organic semiconductor nanofibers within an elastomer matrix.

The organic semiconductor nanofibers may be manufactured using DPPT-TT, represented by Chemical Formula 1 as [poly-[2,5-bis(2-octyldodecyl)-3,6-di(thiophen-2-yl)pyrrolo[3,4-c]pyrrole-1,4(2H,5H)-dionel-alt-thieno[3,2-b]thiophene]].

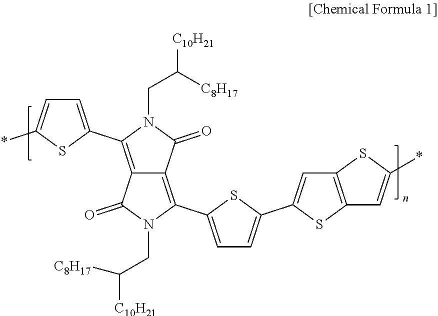

The DPPT-TT may have a weight-average molecular weight of 100,000 g/mol or more.

The elastomer may be an organic elastomer polymer represented by Chemical Formula 2, SEBS (styrene-ethylene-butylene-styrene).

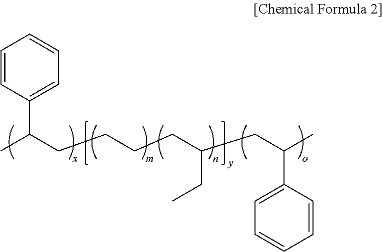

In the SEBS represented by Chemical Formula 2, the composition ratio of (x+o) to (m+n) may range from 18:82 to 20:80.

The nanoweb semiconductor layer may be a DPPT-TT nanofiber SEBS composite film (DPPT-TT:SEBS composite film), in which a layer of organic semiconductor nanofibers is formed within the SEBS matrix through a nano-confinement effect.

The DPPT-TT:SEBS composite film may be manufactured by spin-coating a solution in which DPPT-TT, represented by Chemical Formula 1, and SEBS, represented by Chemical Formula 2, are dissolved in a substance of Chemical Formula 3 at a weight ratio of 1-3:7-9 and at a concentration of 0.6-0.8 wt %.

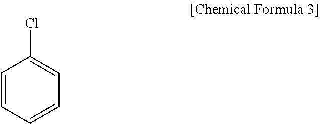

The memory transistor may operate as a flash memory or a WORM (Write Once Read Many) memory depending on the thickness of the floating gate layer when a write voltage and light are applied to perform writing.

The memory transistor may operate as a flash memory when the thickness of the floating gate layer is 15 to 20 nm and as a WORM (Write Once Read Many) memory when the thickness of the floating gate layer is 1 to 10 nm, in cases where writing is performed using a write voltage and light.

The memory transistor may further comprise a control gate layer formed on the lower surface of the blocking dielectric layer, wherein metal nanoparticles are deposited in particulate form through thermal evaporation to provide stretchability; a stretchable protective layer laminated on the upper surface of the tunneling dielectric layer; and an electrode layer including a source electrode layer and a drain electrode layer, which are spaced apart to form a channel in the nanoweb semiconductor layer and laminated on the upper surface of the stretchable protective layer.

The control gate layer may be formed to a thickness of 40 to 60 nm.

An embodiment provides a method for manufacturing a memory transistor, comprising forming a control gate layer and a substrate laminate, wherein metal nanoparticles are deposited in particulate form on a stretchable substrate through thermal evaporation to create a stretchable planar structure; forming a floating gate layer and tunneling dielectric layer laminate, wherein metal nanoparticles are deposited in particulate form through thermal evaporation on a stretchable tunneling dielectric layer to create a stretchable planar structure; forming a stretchable blocking dielectric layer on the surface of the control gate layer of the control gate layer and substrate laminate; transferring the floating gate layer and tunneling dielectric layer laminate onto the surface of the control gate layer and substrate laminate such that the floating gate layer is bonded to the blocking dielectric layer; and transferring a nanoweb semiconductor layer onto the surface of the tunneling dielectric layer of the floating gate layer and tunneling dielectric layer laminate.

In the step of forming the control gate layer and substrate laminate, the substrate may be formed by spin-coating an elastomer solution of SEBS (styrene-ethylene-butylene-styrene), an organic elastomer polymer represented by Chemical Formula 2.

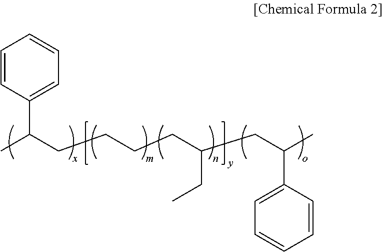

In the SEBS represented by Chemical Formula 2, the composition ratio of (x+o) to (m+n) may range from 18:82 to 20:80.

The step of forming the blocking dielectric layer may involve spin-coating an elastomer solution to produce an elastomer film with a thickness of 750 to 900 nm, which is then transferred onto the control gate layer and substrate laminate to form the blocking dielectric layer.

In the step of manufacturing the floating gate layer and tunneling dielectric layer laminate, the tunneling dielectric layer may be formed by spin-coating an elastomer solution to a thickness of 25 to 100 nm.

In the step of manufacturing the floating gate layer and tunneling dielectric layer laminate, the floating gate layer may be formed by thermally evaporating metal nanoparticles onto the tunneling dielectric layer to a thickness of 1 to 20 nm.

The nanoweb semiconductor layer may be a DPPT-TT nanofiber SEBS composite film (DPPT-TT:SEBS composite film), in which a layer of organic semiconductor nanofibers is formed within the SEBS matrix through a nano-confinement effect.

The organic semiconductor nanofibers may be formed using DPPT-TT, represented by Chemical Formula 1 as [poly-[2,5-bis(2-octyldodecyl)-3,6-di(thiophen-2-yl)pyrrolo[3,4-c]pyrrole-1,4(2H,5H)-dionel-alt-thieno[3,2-b]thiophene]].

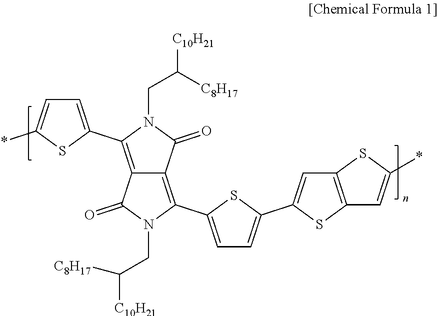

The DPPT-TT:SEBS composite film may be manufactured by spin-coating a solution in which DPPT-TT, represented by Chemical Formula 1, and SEBS, represented by Chemical Formula 2, are dissolved in a substance of Chemical Formula 3 at a weight ratio of 1-3:7-9 and at a concentration of 0.6-0.8 wt %.

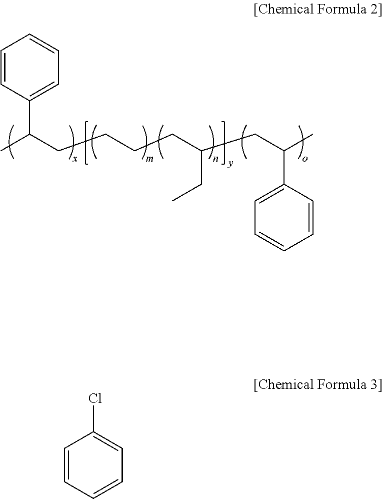

An embodiment provides a memory device comprising a stretchable substrate; one or more wordlines spaced apart and arranged along a first direction on the upper surface of the stretchable substrate; an active layer laminated on the stretchable substrate and the one or more wordlines, including one or more stretchable floating gate layers arranged in a lattice pattern; one or more bitlines spaced apart and arranged along a second direction perpendicular to the first direction on the upper surface of the active layer; and a stretchable protective layer laminated on the active layer and the one or more bitlines, wherein the stretchable floating gate layer includes metal nanoparticles deposited in particulate form on a tunneling dielectric layer through thermal evaporation to form a stretchable planar structure.

The active layer may include a blocking dielectric layer formed of an elastomer film and laminated on the stretchable substrate and the one or more wordlines; the stretchable floating gate layer laminated on the blocking dielectric layer at the intersection regions of the wordlines and bitlines; a tunneling dielectric layer formed of an elastomer film and laminated on the blocking dielectric layer and the floating gate layer; and a nanoweb semiconductor layer laminated on the tunneling dielectric layer.

The active layer may operate as an active layer of a flash memory when writing is performed using a write voltage and light.

The active layer may operate as an active layer of a WORM (Write Once Read Many) memory when writing is performed by applying a write voltage and light.

An embodiment provides a method for manufacturing a memory device, comprising depositing one or more wordlines spaced apart along a first direction on a stretchable substrate; transferring a blocking dielectric layer onto a surface of the stretchable substrate on which the wordlines are deposited; depositing one or more stretchable floating gate layers in regions of the blocking dielectric layer where the wordlines are positioned underneath; transferring a tunneling dielectric layer onto the surface where the floating gate layers are formed; transferring a nanoweb semiconductor layer onto the surface of the tunneling dielectric layer; and depositing source lines and drain lines spaced apart along a second direction perpendicular to the first direction on the surface of the nanoweb semiconductor layer.

The active layer, memory transistor, and memory device of the present invention provide sufficient stretchability to preserve recorded data and prevent mechanical failure even under mechanical deformation, enabling the integration of floating gate memory transistors into electronic skin devices.

Furthermore, in the memory transistor and memory device of the present invention, the active layer may function as an active layer of a flash memory or a WORM memory depending on the thickness of the floating gate layer when writing is performed using a write voltage and light.

Accordingly, the memory transistor and memory device of the embodiment can selectively function as a flash memory or a WORM memory. This makes it highly applicable for secure data storage in various fields, including electronic skin, wearable devices, stretchable sensors, displays, and electronic circuits.

The effects of the present invention are not limited to those mentioned above, and other effects not explicitly stated may be understood by those skilled in the art from the descriptions provided below.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 is a cross-sectional view of the active layer of a stretchable floating gate-based memory transistor according to an embodiment of the present invention.

FIG. 2 is a cross-sectional view of a stretchable floating gate-based memory transistor according to an embodiment of the present invention.

FIG. 3 is a flowchart illustrating the process steps of a method for manufacturing a stretchable floating gate-based memory transistor.

FIGS. 4A to 4C are diagrams illustrating the manufacturing process of a stretchable floating gate-based memory transistor.

FIG. 5 shows a layered structure of the stretchable floating gate-based memory device according to an embodiment of the present invention.

FIG. 6 illustrates the characteristics of a stretchable floating gate memory transistor.

FIG. 7 shows a comparison image between a silicon wafer before Ag deposition and a TDL/silicon wafer with Ag thermally evaporated onto the TDL.

FIG. 8 is an HR-TEM image of thermally evaporated Ag nanoparticles on SEBS TDL.

FIG. 9 is a graph showing the X-ray photoelectron spectroscopy (XPS) spectrum with depth profiling for the Ag FG-SEBS composite layer.

FIGS. 10A to 10C are EDS mapping images of electrons (FIG. 10A), carbon (C) (FIG. 10B), and silver (Ag) atoms (FIG. 10C) using STEM.

FIGS. 11A to 11D include HR-TEM images of Ag nanoparticles in the TDL (FIGS. 11A, 11B, and 11C) and a graph (FIG. 11D) showing the estimated sizes of Ag nanoparticles analyzed using the “Image J” software.

FIGS. 12A and 12B are graphs showing the transfer characteristics (VD=−10 V) of a memory transistor without an FG (FIG. 12A) and with an FG (FIG. 12B). L1 represents the transfer characteristics of the initial state (before writing), while L2 represents the transfer characteristics after writing (white light, 10 mW/cm², 50 VG, and 5 seconds).

FIGS. 13A, 13B, and 13C show the transfer characteristics during writing as a function of VG, light intensity, and writing time, while keeping other parameters constant.

FIGS. 13D, 13E, and 13F show the changes in ID at VG=0 V and Vth as a function of VG, light intensity, and writing time.

FIG. 13G illustrates the band diagram of the memory transistor's operating mechanism in the embodiment.

FIG. 14A shows the breakdown voltage of BDLs with varying thicknesses in a metal-insulator-metal (MIM) structure, and FIG. 14B illustrates the memory window of transistors under BDLs of varying thicknesses with fixed FG (5 nm) and TDL (100 nm) thicknesses.

FIG. 15A presents a graph of the breakdown voltage of dielectric layers with varying TDL thicknesses in an MIM structure with fixed BDL (900 nm) and FG (5 nm) thicknesses, while FIG. 15B shows the memory window of transistors under varying TDL thicknesses with fixed FG (5 nm) and TDL (100 nm) thicknesses.

FIG. 16A is a cross-sectional diagram of a floating gate memory transistor for low-power operation using thin dielectric layers, FIG. 16B is a graph showing the transfer characteristics (VD=−5 V) as a function of the writing voltage under 830 nm light (NIR, 1 mW/cm²), FIG. 16C illustrates the memory window, and FIG. 16D shows the memory on/off ratio as a function of the writing voltage (VG=0 V).

FIG. 17A depicts the transfer characteristics (VD=−10 V) of a memory transistor in the pristine state, FIG. 17B shows the characteristics after writing (conditions: white light, 50 VG, 5 seconds, and 10 mW/cm²), and FIG. 17C illustrates the memory on/off ratio (VG=0 V).

FIG. 18A is a graph showing the normalized drain current after the writing process (white light, 10 mW/cm², 50 VG, and 5 seconds) as a function of Ag FG thickness. FIG. 18B shows the characteristic time (T) and dispersion parameter (β) calculated from the normalized drain current using the mathematical expression.

FIG. 19 is a graph of the work functions of Ag FG, OSC, and Ag S/D measured using PESA.

FIG. 20 shows an XPS spectrum of the Ag 3d peak at various etching times, and FIG. 21 shows the XPS spectrum of Ag and silver oxide (AgXO) peaks at different etching times.

FIG. 22 is a diagram illustrating the current-voltage relationship of a device for the tunneling effect.

FIGS. 23A and 23B are XPS depth profiles of an Ag-embedded tunneling dielectric layer (TDL) before programming (FIG. 23A) and after programming (FIG. 23B), with Ag and carbon atoms representing the Ag floating gate and TDL, respectively.

FIGS. 24A to 24G illustrate the transfer characteristics and drain current changes of memory transistors after the writing process under different light conditions.

FIGS. 25A to 25D depict the writing, erasing, and retention characteristics of the memory transistor in the embodiment.

FIGS. 26A to 26L present the physical and electrical characteristics of stretchable non-volatile memory transistors incorporating a stretchable floating gate layer in the embodiment.

FIG. 27A shows AFM height images of the pristine state, FIG. 27B under 50% uniaxial strain deformation, and FIG. 27C under 30% biaxial strain deformation.

FIGS. 28A and 28B are graphs showing the transfer characteristics (VD=−10 V) of the memory transistor as a function of the write-stretching sequence under uniaxial stretching deformation in the directions parallel (FIG. 28A) and perpendicular (FIG. 28B) to the channel.

FIG. 29 illustrates the transfer characteristics (VD=−10 V) of the memory transistor as a function of the write-stretching sequence under biaxial strain deformation.

FIGS. 30A to 30D present graphs of the transfer characteristics (VD=−10 V) of the memory transistor programmed with the write-stretching sequence under 50% uniaxial stretching cycles in various directions.

FIGS. 31A and 31B show the transfer characteristics (VD=−10 V) of the memory transistor programmed with the write-stretching sequence under 30% biaxial stretching cycles (FIG. 31A) and after the strain was released (FIG. 31B).

FIGS. 32A and 32B illustrate the transfer characteristics (VD=−10 V) of the memory transistor programmed with the stretch-writing sequence under uniaxial stretching in parallel (FIG. 32A) and perpendicular (FIG. 32B) directions.

FIG. 33 shows the transfer characteristics (VD=−10 V) of the memory transistor programmed with the stretch-writing sequence under biaxial strain deformation.

FIGS. 34A to 34F present graphs of the transfer characteristics (VD=−10 V) and field-effect mobility during writing (50 VG, 5 s, 10 mW/cm² white light) under various stretching directions.

FIGS. 35A and 35B are graphs showing the frequency-capacitance characteristics of the dielectric material in the memory transistor under uniaxial (FIG. 35A) and biaxial (FIG. 35B) strain deformation.

FIGS. 36A to 36G depict the reliability evaluation results of the stretchable memory transistor.

FIGS. 37A and 37B show the OM image (FIG. 37A) and transfer characteristics (VD=−10 V) (FIG. 37B) of the memory transistor after the writing process during a peel-off test using 3M Tape™ (Model: Magic Tape 810, adhesive strength: 2.2 N/cm).

FIG. 38 is a graph showing the transfer characteristics (VD=−10 V) of the memory transistor after the writing process under various ambient air conditions.

FIG. 39 illustrates the transfer characteristics (VD=−10 V) of the memory transistor after the writing process at various temperatures.

FIGS. 40A to 40D present the transfer characteristic curves and Arrhenius plots for calculating activation energy before and after the writing process at various temperatures.

FIGS. 41A and 41B depict the transfer characteristics (VD=−10 V) and memory on/off ratio during wafer soaking.

FIG. 42 shows the characteristics of a memory device (100) with a skin-type active matrix memory transistor array.

FIG. 43 illustrates the manufacturing process of a memory device with a stretchable active matrix (7×7) memory transistor array.

FIG. 44 is a graph showing the transfer characteristics (VD=−10 V) of all unit cells in the pristine active matrix array.

FIGS. 45A to 45D depict the selective programming process and threshold voltage mapping in the active matrix array.

FIG. 46 shows the transfer characteristics (VD=−10 V) of all unit cells in a programmed active matrix array following an ASCII code pattern spelling “Storage.”

FIG. 47 presents the transfer characteristics (VD=−10 V) of all unit cells in the programmed active matrix array after ball indentation for the ASCII code spelling “Storage.”

### DETAILED DESCRIPTION OF THE DISCLOSURE

The specific structural or functional descriptions of embodiments according to the concept of the present invention disclosed herein are merely provided as examples to describe the embodiments and are not intended to limit the concept of the present invention. The embodiments according to the concept of the present invention may be implemented in various forms and are not limited to the embodiments described herein.

The embodiments according to the concept of the present invention may undergo various modifications and take on numerous forms. Therefore, the embodiments are illustrated in the drawings and described in detail herein. However, this is not intended to limit the embodiments of the present invention to specific disclosed forms, but rather to encompass variations, equivalents, or substitutes included within the spirit and scope of the present invention.

Terms such as “first,” “second,” and the like may be used to describe various components, but these components should not be limited by these terms. Such terms are only used to distinguish one component from another. For example, a “first” component could be referred to as a “second” component without departing from the scope of the present invention, and similarly, a “second” component could be referred to as a “first” component.

When a component is said to be “connected to” or “coupled to” another component, it should be understood that the component may be directly connected or coupled to the other component, or there may be intervening components. Conversely, when a component is said to be “directly connected to” or “directly coupled to” another component, it should be understood that no intervening components are present. Expressions describing relationships between components, such as “between” and “directly between” or “adjacent to” and “directly adjacent to,” should be interpreted similarly.

The terms used herein are only intended to describe specific embodiments and are not intended to limit the invention. Singular expressions include plural forms unless the context clearly indicates otherwise. Terms such as “include” or “have” specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical and scientific terms, have the same meanings as commonly understood by one of ordinary skill in the art to which this invention belongs. Terms defined in commonly used dictionaries should be interpreted as having meanings consistent with their context in the related art and not in an overly idealized or formal sense unless expressly defined otherwise herein.

Hereinafter, embodiments will be described in detail with reference to the accompanying drawings. However, the scope of the patent application is not limited or restricted by these embodiments. The same reference numerals in the respective drawings denote the same elements.

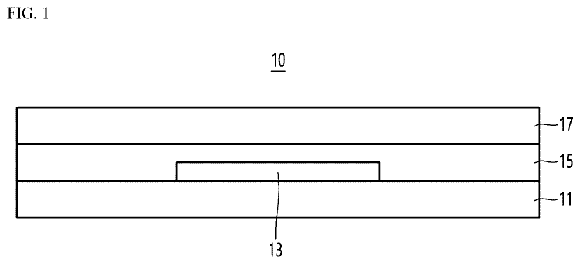

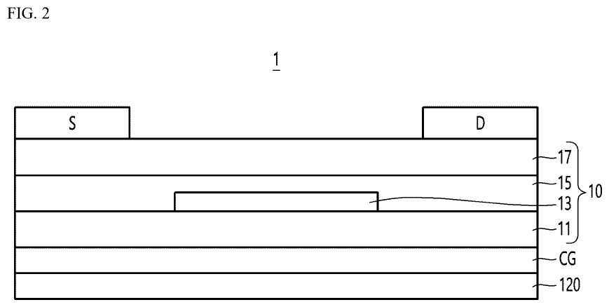

FIG. 1 is a cross-sectional view of the active layer of a stretchable floating gate-based memory transistor according to an embodiment of the present invention, and FIG. 2 is a cross-sectional view of the stretchable floating gate-based memory transistor according to an embodiment of the present invention.

As shown in FIGS. 1 and 2, the memory transistor (1) may include an active layer (10) comprising a stretchable floating gate layer (13).

The active layer (10) may be configured to include a blocking dielectric layer (11) formed of an elastomer film, a stretchable floating gate layer (13) laminated on the upper surface of the blocking dielectric layer (11), a tunneling dielectric layer (15) formed of an elastomer film and laminated on the upper surfaces of the blocking dielectric layer (11) and the floating gate layer (13), and a nanoweb semiconductor layer (17) laminated on the upper surface of the tunneling dielectric layer (15).

In this case, the stretchable floating gate layer (13) is formed as a stretchable planar structure by depositing conductive metal nanoparticles in particulate form onto the tunneling dielectric layer (15) through thermal evaporation.

The metal nanoparticles may include one or more selected from the group consisting of silver (Ag), copper (Cu), aluminum (Al), nickel (Ni), chromium (Cr), platinum (Pt), gold (Au), and indium tin oxide (ITO).

The blocking dielectric layer (11) may be formed by spin-coating an elastomer solution to a thickness of 750 to 950 nm, thereby forming an electric field while blocking charge movement.

The tunneling dielectric layer (15) may be formed by spin-coating an elastomer solution to a thickness of 25 to 100 nm, enabling charge movement to the floating gate layer (13) through the Fowler-Nordheim tunneling effect.

The floating gate layer (13) may be formed as a stretchable planar structure with a thickness of 1 to 20 nm by depositing the metal nanoparticles in particulate form through thermal evaporation.

The nanoweb semiconductor layer (17) may be formed as a film in which organic semiconductor nanofibers are mixed within an elastomer matrix.

The organic semiconductor used to form the organic semiconductor nanofibers may be DPPT-TT, represented by Chemical Formula 1 as [poly-[2,5-bis(2-octyldodecyl)-3,6-di(thiophen-2-yl)pyrrolo[3,4-c]pyrrole-1,4(2H,5H)-dionel-alt-thieno[3,2-b]thiophene]].

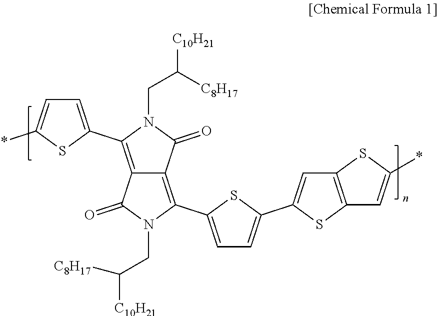

The DPPT-TT may have a weight-average molecular weight of 100,000 g/mol or more.

The elastomer may be an organic elastomer polymer represented by Chemical Formula 2, SEBS (styrene-ethylene-butylene-styrene).

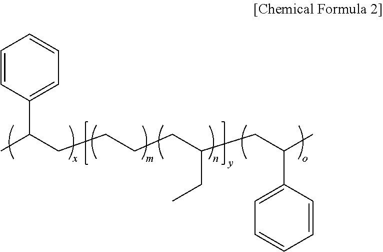

In the SEBS represented by Chemical Formula 2, the composition ratio of (x+o) to (m+n) may range from 18:82 to 20:80.

The elastomer matrix organic semiconductor nanofiber composite film may be a DPPT-TT nanofiber SEBS composite film (DPPT-TT:SEBS composite film), in which a layer of organic semiconductor nanofibers is formed within the SEBS matrix through a nano-confinement effect.

The DPPT-TT:SEBS composite film may be manufactured by spin-coating a solution in which DPPT-TT, represented by Chemical Formula 1, and SEBS, represented by Chemical Formula 2, are dissolved in a substance of Chemical Formula 3 at a weight ratio of 1-3:7-9 and at a concentration of 0.6-0.8 wt %.

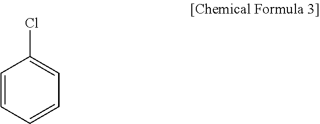

As shown in FIG. 2, the memory transistor (1) may further include a stretchable substrate (120) onto which the blocking dielectric layer (11) is transferred, a control gate layer (CG) formed on the lower surface of the blocking dielectric layer (11), wherein metal nanoparticles are deposited in particulate form through thermal evaporation to provide stretchability, a stretchable protective layer (150) laminated on the upper surface of the tunneling dielectric layer, and an electrode layer including a source electrode layer (S) and a drain electrode layer (D), which are spaced apart to form a channel in the nanoweb semiconductor layer (17) and laminated on the upper surface of the stretchable protective layer (150).

The stretchable substrate (120) may be manufactured by mixing the material of Chemical Formula 2 into the material of Chemical Formula 4 at a concentration of 90-110 mg/mL, followed by spin-coating onto a rigid substrate.

The blocking dielectric layer (11) may be an SEBS matrix formed by mixing the material of Chemical Formula 2 into the material of Chemical Formula 4 at a concentration of 50-70 mg/mL, followed by spin-coating onto a rigid substrate to achieve a thickness of 750 to 900 nm.

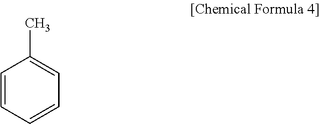

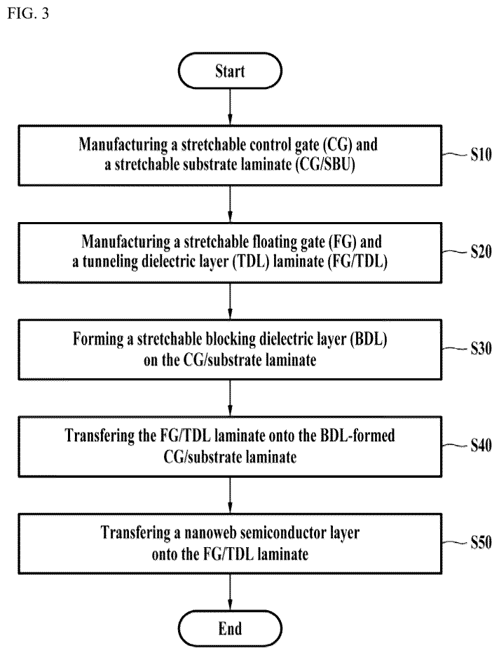

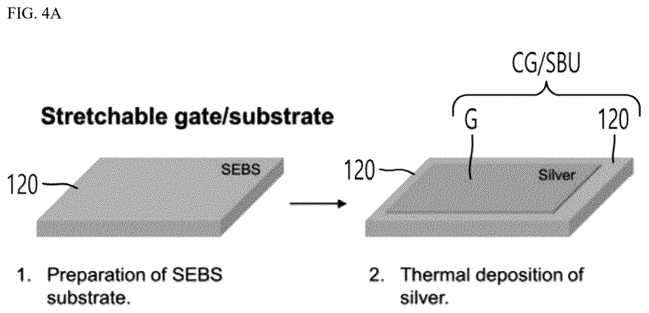

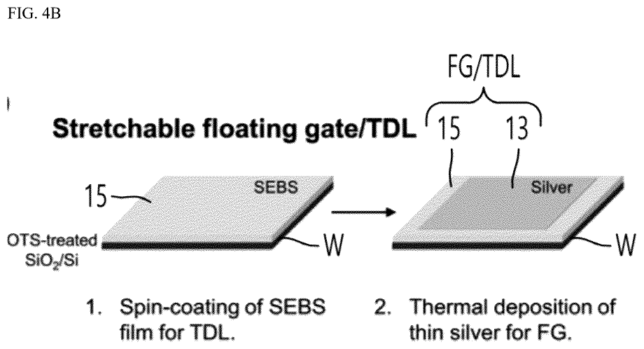

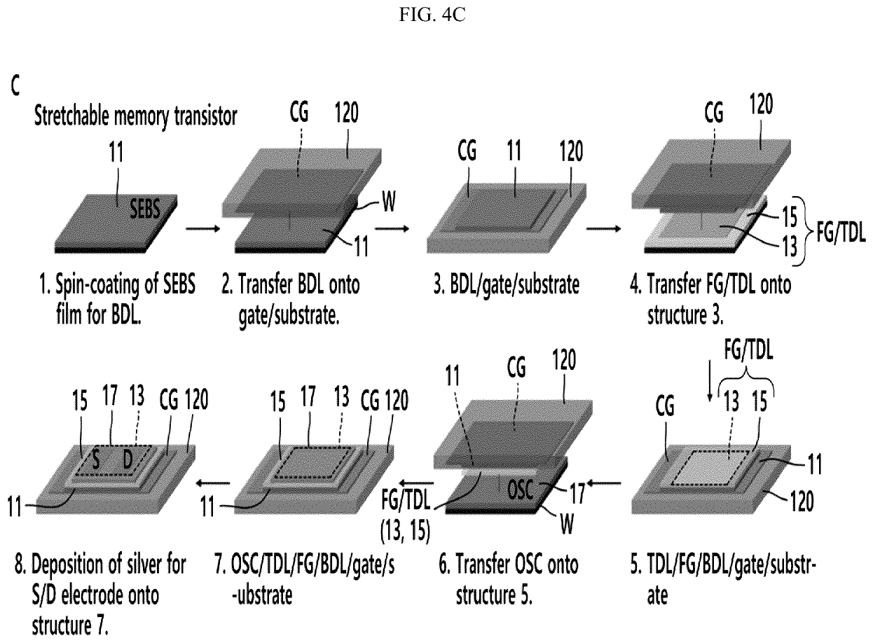

FIG. 3 is a flowchart illustrating the process steps of a method for manufacturing a stretchable floating gate-based memory transistor, and FIGS. 4A to 4C are diagrams illustrating the manufacturing process of the stretchable floating gate-based memory transistor.

FIG. 4A represents the stretchable gate/substrate laminate, FIG. 4B represents the floating gate/TDL laminate, and FIG. 4C represents the process of transferring the floating gate/TDL laminate onto the stretchable gate/substrate laminate.

As shown in FIGS. 3 and 4, the method for manufacturing a memory transistor according to the embodiment may include:
Step S10: Fabricating a control gate layer and substrate laminate, wherein metal nanoparticles are deposited in particulate form on a stretchable substrate through thermal evaporation to form a stretchable planar structure.
Step S20: Fabricating a floating gate layer and tunneling dielectric layer laminate by laminating a floating gate layer, wherein metal nanoparticles are deposited in particulate form on a stretchable tunneling dielectric layer through thermal evaporation to form a stretchable planar structure.
Step S30: Forming a stretchable blocking dielectric layer on the surface of the control gate layer of the control gate layer and substrate laminate.
Step S40: Transferring the floating gate layer and tunneling dielectric layer laminate onto the surface of the control gate layer and substrate laminate such that the floating gate layer is bonded to the blocking dielectric layer.
Step S50: Transferring a nanoweb semiconductor layer (17) onto the surface of the tunneling dielectric layer of the floating gate layer and tunneling dielectric layer laminate.

In Step S10, during the fabrication of the stretchable control gate layer and substrate laminate, the stretchable substrate (120) may be formed by spin-coating an elastomer solution of SEBS, an organic elastomer polymer represented by Chemical Formula 2. At this time, in SEBS represented by Chemical Formula 2, the composition ratio of (x+o) to (m+n) may range from 18:82 to 20:80.

In Step S30, during the formation of the blocking dielectric layer, the blocking dielectric layer (11) may be formed by spin-coating an elastomer solution at a concentration of 40 mg/mL onto the SiO₂ layer of an Si wafer treated with silane coupling agents (methacryloxypropyltrimethoxysilane; MPS, and octadecyltrichlorosilane; OTS) to achieve a thickness of 750 to 900 nm. The layer may then be transferred onto the control gate layer and substrate laminate (CG/SUB) to form the blocking dielectric layer.

The control gate layer (CG) may be formed on the surface of the blocking dielectric layer (11) by depositing metal nanoparticles in particulate form through thermal evaporation, creating a stretchable structure with a thickness of 40 to 60 nm.

In Step S20, during the fabrication of the floating gate layer and tunneling dielectric layer laminate, the tunneling dielectric layer (15) may be formed by spin-coating an elastomer solution at a concentration of 4 to 11 mg/mL onto the SiO2 layer of an Si wafer treated with silane coupling agents (MPS and OTS) to achieve a thickness of 25 to 100 nm.

In Step S20, the floating gate layer (13) may be formed by thermally evaporating metal nanoparticles at a rate of 0.1 to 0.3 nm/s onto the tunneling dielectric layer (15) to achieve a thickness of 1 to 20 nm.

In Step S50, during the transfer of the nanoweb semiconductor layer onto the tunneling dielectric layer, the nanoweb semiconductor layer (17) may be the DPPT-TT nanofiber SEBS composite film.

In the above-described method for manufacturing the memory transistor, the fabrication of the control gate layer and substrate laminate (Step S10) and the fabrication of the floating gate layer and tunneling dielectric layer laminate (Step S20) may be performed in any order.

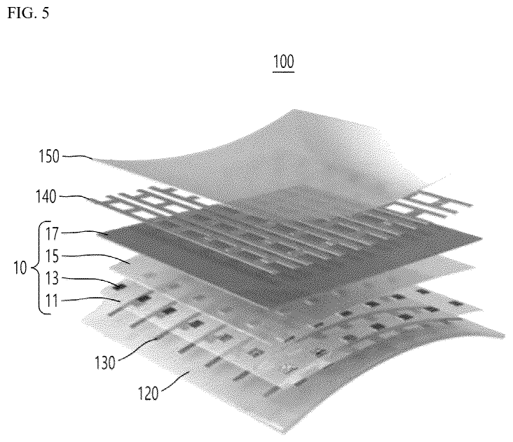

FIG. 5 illustrates the layered structure of the stretchable floating gate-based memory device (100) according to an embodiment of the present invention.

As shown in FIG. 5, the memory device (100) of the embodiment may include, in sequential order: a stretchable substrate (120), one or more wordlines (130), an active layer (10), one or more bitlines (140), and a stretchable protective layer (150).

The stretchable substrate (120) may be fabricated as described above by mixing the material of Chemical Formula 2 into the material of Chemical Formula 4 at a concentration of 90 to 110 mg/mL, followed by spin-coating onto a rigid substrate.

The one or more wordlines (130) may be formed by deposition using a shadow mask or similar technique, arranged along the first direction (x-direction) on the upper surface of the stretchable substrate, spaced apart from each other.

The active layer (10) may include one or more stretchable floating gate layers (13) arranged in a lattice pattern, laminated on the stretchable substrate (120) and the one or more wordlines (130).

As shown in FIGS. 1, 2, and 5, the active layer (10) may include a blocking dielectric layer (11), a stretchable floating gate layer (13), a tunneling dielectric layer (15), and a nanoweb semiconductor layer (17), laminated sequentially in the upward direction (z-direction). This structure is configured to form an active region for charge movement according to the applied voltage.

The one or more bitlines (140) may be formed by deposition using a shadow mask or similar technique, arranged along the second direction (y-direction), perpendicular to the first direction, on the upper surface of the active layer (10), spaced apart from each other.

The stretchable protective layer (150) may be laminated on the upper surface of the active layer (10) and the one or more bitlines (140).

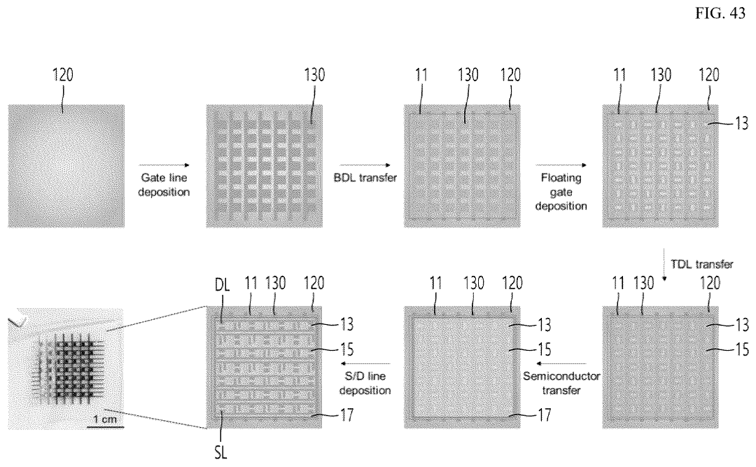

A method for manufacturing a memory device according to an embodiment of the present invention (refer to FIG. 43) may include:
Depositing one or more wordlines arranged along the first direction, spaced apart from each other, on a stretchable substrate (120).
Transferring the blocking dielectric layer onto the surface of the stretchable substrate where the wordlines (130) are deposited.
Depositing one or more stretchable floating gate layers in the regions of the blocking dielectric layer where the wordlines (130) are located underneath.
Transferring the tunneling dielectric layer onto the surface of the floating gate layer (13).
Transferring the nanoweb semiconductor layer onto the surface of the tunneling dielectric layer (15).
Depositing source lines (SL) and drain lines (DL) along the second direction, perpendicular to the first direction, spaced apart from each other, on the surface of the nanoweb semiconductor layer (17).

The memory transistor (1) and memory device (100) with the above-described configuration provide sufficient stretchability to preserve recorded data and prevent mechanical failure even under mechanical deformation. This enables the integration of floating gate memory transistors into electronic skin devices.

Additionally, in the memory transistor (1) and memory device (100) with the above-described configuration, the active layer (10) may operate as the active layer of a flash memory when the thickness of the floating gate (13) is 15 to 20 nm and writing is performed using a write voltage and light. Similarly, the active layer (10) may operate as the active layer of a WORM (Write Once Read Many) memory when the thickness of the floating gate (13) is 1 to 10 nm and writing is performed using a write voltage and light.

Accordingly, the memory transistor (1) and memory device (100) according to the embodiment can selectively function as a flash memory or a WORM memory. This makes them highly useful for secure data storage in various fields, such as electronic skin, wearable devices, stretchable sensors, displays, and electronic circuits.

### Example

This embodiment of the present invention introduces an inherently stretchable polymer FG (Floating Gate) memory transistor for long-term data storage and security of personal data in e-skin devices. A dual-stimulus (optical and electrical) writing system for WORM (Write Once Read Many) memory was designed using the stretchable FG memory transistor. Compared to conventional voltage-driven (single-stimulus) memory, the dual-stimulus (electrical and optical) driven memory leverages the advantages of both stimuli, enabling the recording of multiple digital data. Furthermore, data written using dual stimuli was difficult to erase using a single stimulus, akin to a dual-lock system. As a result, integrating FG and photoactive semiconductors into stretchable transistors offers significant advantages in terms of enhanced optical sensitivity and data storage capabilities.

The FG memory transistor fabricated according to this embodiment exhibited typical characteristics, including linear mobility (μlin, 0.19±0.03 cm²/(V·s)) without electrical hysteresis and a high on/off ratio (>10⁵). After a writing process involving light and positive gate bias (VG), the WORM memory transistor demonstrated a high memory on/off ratio (Iwrite/Ipristine>10⁵ at VG=0 V), a large memory window (17 V), and long retention times (>10⁶ seconds).

In addition, the memory transistor displayed inherent stretchability (50% uniaxial strain or 30% biaxial strain) and mechanical durability over multiple stretching cycles (1,000 cycles). It also exhibited excellent environmental stability (temperature, humidity, air, and peeling resistance), making it suitable for e-skin memory devices. Finally, a 7×7 active matrix memory transistor array was fabricated for storing personalized e-skin data.

### 1. Materials

Poly[(dithiophenyl)-alt-(2,5-bis(2-octyldodecyl)-3,6-bis(thiophenyl)-diketopyrrolopyrrole)](DPPT-TT), styrene-ethylene-butylene-styrene (SEBS), polydimethylsiloxane (PDMS, Sylgard 184), curing agent, trichloro(octadecyl)silane (OTS) solution, anhydrous chlorobenzene, and anhydrous toluene were procured. Silicon wafers (SiO2/Si, <100>, 1-30 ohm, 300 nm SiO2) were also procured.

EBS H1062 (S/EB weight ratio, 18/82) was used for the nanoweb semiconductor layer and the stretchable substrate. SEBS H1052 (S/EB weight ratio, 20/80) was used for the blocking dielectric layer and tunneling dielectric layer. Ag nanoparticles (99.99%, 3-5 mm granules) were used as gate electrodes, floating gates, and source/drain electrodes. All chemicals and materials were used without further purification.

### 2. Fabrication of Memory Transistor and Device

The nanoweb semiconductor layer (17) was fabricated by spin-coating a semiconductor solution (0.7 wt % DPPT-TT and SEBS H1062 in anhydrous chlorobenzene at a weight ratio of 2:8) onto an OTS-treated silicon wafer at 800 rpm for 1 minute. The nanoweb semiconductor layer (17) was then annealed at 180° C. for 1 hour. All processes were conducted in an N2 glove box environment (H₂O<0.01 ppm, O₂<0.01 ppm).

The stretchable substrate (120) was prepared by casting SEBS H1062 solution (100 mg/mL in anhydrous toluene) onto a glass substrate and allowing it to dry overnight. SEBS H1052 solutions were prepared in anhydrous toluene for the tunneling dielectric layer (TDL, 15) and blocking dielectric layer (BDL, 11).

The BDL (11) solution was spin-coated onto OTS-treated SiO2 at concentrations of 40 mg/mL (1000 rpm, 750 nm) and 50 mg/mL (1000 rpm, 900 nm, or 1500 rpm, 750 nm). The TDL (15) solution was spin-coated at concentrations of 5 mg/mL (1000 rpm, 50 nm) and 10 mg/mL (1000 rpm, 100 nm, or 1500 rpm, 75 nm).

After preparing the TDL film (15), Ag nanoparticles were thermally evaporated onto the TDL (15) at a rate of 0.2 nm/s to form a floating gate/TDL layer (FG/TDL) with a thickness of 1-20 nm.

For the control gate layer (CG), Ag was thermally evaporated onto the SEBS stretchable substrate at a rate of 0.2 nm/s using a shadow mask until a thickness of 50 nm was achieved. Using the Ag gate/SEBS, the blocking dielectric layer (BDL, 11), Ag floating gate layer and tunneling dielectric layer laminate (Ag FG/TDL), and nanoweb semiconductor layer (17) were sequentially transferred to form a structure comprising a semiconductor/TDL/Ag FG/BDUAg gate/SEBS substrate.

Finally, 50 nm thick Ag source and drain electrodes (S/D) were thermally evaporated at a rate of 0.2 nm/s according to a shadow mask pattern, completing the fabrication of the inherently stretchable floating gate memory transistor.

The fabrication process of the active layer (10) followed the same process as the transistor device, except for the blocking dielectric layer (BDL, 11), where a thicker BDL film (1300 nm) was used to ensure stable operation and reduce leakage current. All deposition processes were carried out under high vacuum (<5×10⁻⁶ torr). The channel length and width of the transistor and active layer (10) were 150 μm and 1000 μm, respectively.

### 3. Characterization

To stabilize the devices, all devices were aged overnight in an automatic desiccator (humidity 24%, 27° C.). Electrical characteristics were measured under ambient conditions using a KEITHLEY 4200 probe station and a vacuum probe station connected to a KEITHLEY 2636B for temperature control. Dielectric capacitance of the BDL and TDL was measured using an LCR meter (Keysight 4274A) connected to a probe station.

Electrical performance under various light colors was evaluated using near-infrared (830 nm, Thorlabs CPS830), red (635 nm, Thorlabs CPS635), green (520 nm, Thorlabs CPS520), and blue (450 nm, Thorlabs CPS450) light sources. White light was provided by a white LED, and its intensity was measured using a lux meter (VICTOR 1010). The light intensity was converted from lux to W/cm² using a conversion factor (6,830,000 lux=1 W/cm²).

UV-Vis-NIR spectroscopy was performed using a Jasco V-770 spectrophotometer. Film thickness was measured using an ellipsometer (WONWOO STRC-2000). Surface morphology was analyzed under ambient conditions using an atomic force microscope (AFM, Bruker MultiMode 8-HR) and an optical microscope (OM, Leica 2DM4 M). High-resolution transmission electron microscopy (HR-TEM) and scanning transmission electron microscopy (STEM) images were obtained using a JEM-2100F (JEOL), and particle sizes were calculated using ‘Image J’ software.

XPS measurements were performed using a K-Alpha system (Thermo Electron). Stretched OM and AFM images of the semiconductor were obtained from the semiconductor transferred using the PDMS stamp method. Surface expansion was calculated from the change in line length before and after indentation.

### 4. Results

### 4-1. Stretchable Floating Gate Memory Transistor

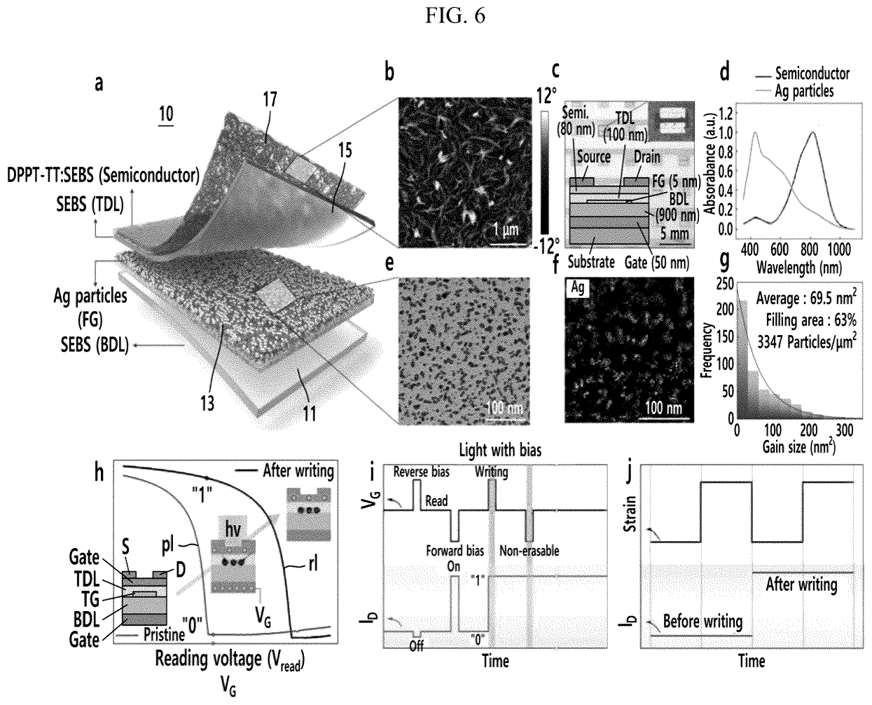

FIG. 6 illustrates the characteristics of a stretchable floating gate (FG) memory transistor.

Specifically:
(a) of FIG. 6 shows a schematic diagram of the stretchable semiconductor and dielectric.
(b) of FIG. 6 displays the AFM phase image of the semiconductor polymer film.
(c) of FIG. 6 provides an OM image of the transistor matrix array and individual channel (with an inset showing the structure of the memory transistor).
(d) of FIG. 6 is a graph of the UV-Vis-NIR spectrum for the semiconductor polymer film for FG and Ag nanoparticles.
(e) of FIG. 6 presents an HR-TEM image.
(f) of FIG. 6 displays the EDS mapping image of Ag for the FG region.
(g) of FIG. 6 is a graph showing the particle size distribution of Ag nanoparticles derived from the HR-TEM image.
(h) of FIG. shows a schematic of the writing process and transfer curve corresponding to the pristine state and the post-write state.
(i) of FIG. 6 illustrates a schematic of the real-time writing and reading processes.
(j) of FIG. 6 depicts a schematic of ID before and after writing, comparing the device in stretched and unstretched states.

As shown in (a) of FIG. 6, the active layer (10) of the memory transistor (1) is designed as a fully stretchable component with a top-contact, bottom-gate configuration. It includes a nanoweb semiconductor layer (17), a stretchable protective layer (150), S/D electrodes, control gate electrodes, and a floating gate (FG) layer (13). An intrinsically stretchable polymer semiconductor film, known for its high stretchability and performance due to the nano-confinement effect, was prepared by blending poly[(dithienothiophene)-alt-(2,5-bis(2-octyldodecyl)-3,6-bis(thiophenyl)-diketopyrrolopyrrole)](DPPT-TT) and styrene-ethylene-co-butylene-styrene (SEBS).

(b) of FIG. 6 shows the atomic force microscopy (AFM) phase image of the blend film surface, revealing the presence of nanofibers associated with the nano-confinement effect. Ag metallization, performed using a previously reported method, was used to define the stretchable S/D and gate electrodes of the FG memory transistor (1). (c) of FIG. 6 provides an optical microscopy (OM) image of the FG memory transistor array, with an inset schematic of the electrode configuration for individual transistors.

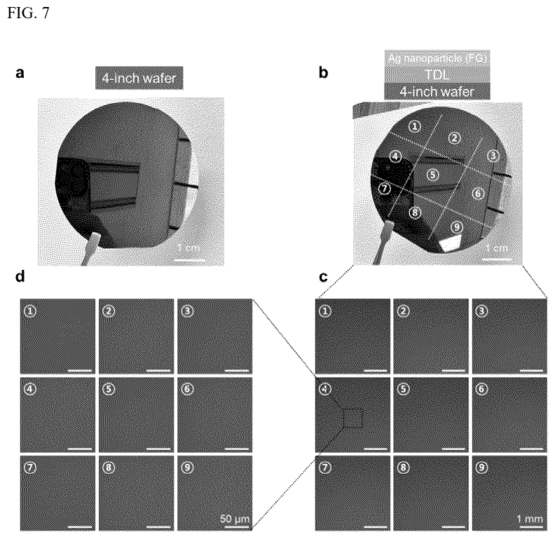

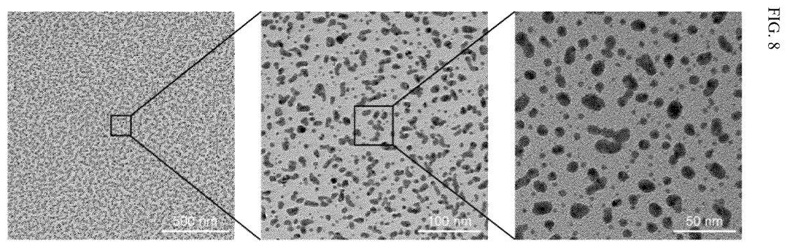

FIG. 7 is a comparison photograph of a silicon wafer before Ag deposition and a TDL/silicon wafer with Ag thermally evaporated onto the TDL.

(a) of FIG. 7 shows a photograph of a 4-inch silicon wafer.

(b) of FIG. 7 displays a photograph of thermally evaporated Ag on a TDL/silicon wafer.

(c) and (d) of FIG. 7 present optical microscopy images of the Ag/TDL/silicon wafer at various magnifications.

As shown in FIG. 7, the stretchable FG was deposited on the backside of the tunneling dielectric layer (TDL) (15) with high uniformity via thermal evaporation of Ag at the 4-inch wafer scale.

Subsequently, a blocking dielectric layer (BDL) was overlaid on the FG, positioning the FG between the TDL and the BDL.

FIG. 8 is an HR-TEM image of thermally evaporated Ag nanoparticles on SEBS TDL.

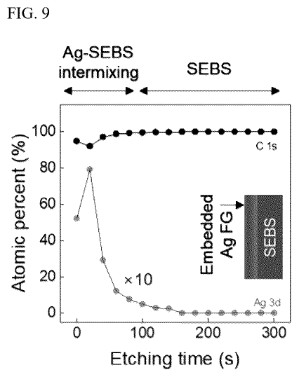

FIG. 9 is a graph showing the X-ray photoelectron spectroscopy (XPS) spectrum obtained through depth profiling of the Ag FG-SEBS blended layer.

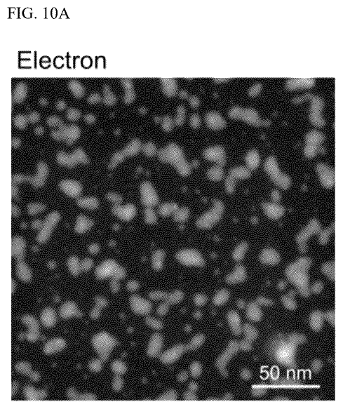

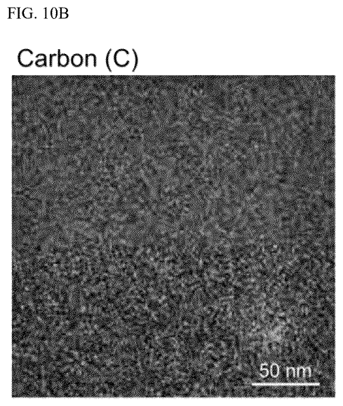

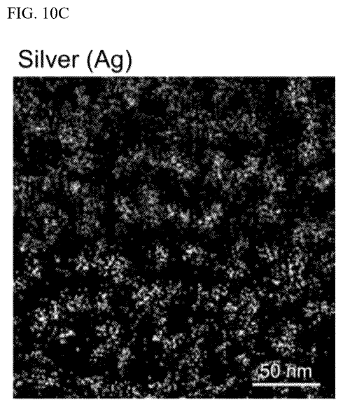

FIGS. 10A to 10C are EDS mapping images obtained using STEM, showing electrons (FIG. 10A), carbon (C) (FIG. 10B), and silver (Ag) atoms (FIG. 10C).

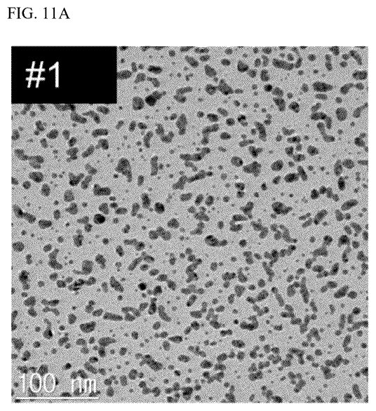

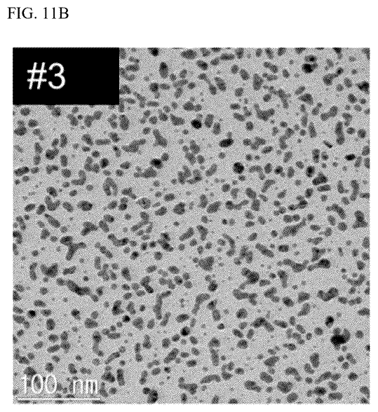

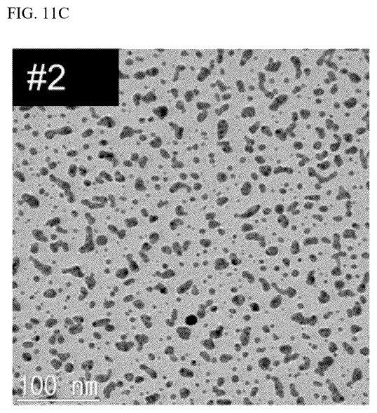

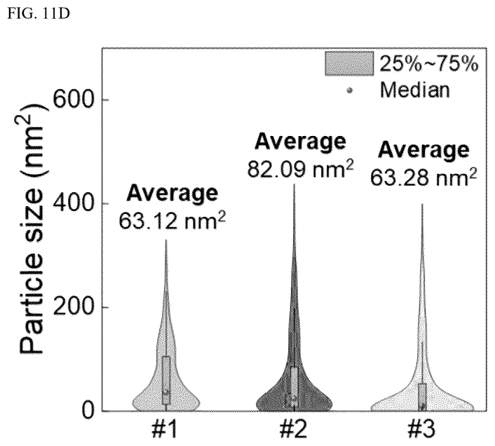

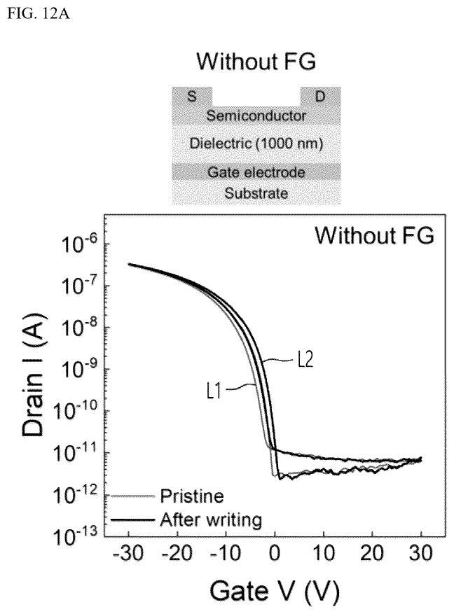

FIGS. 11A to 11D include HR-TEM images of Ag nanoparticles on TDL (FIGS. 11A, 11B, and 11C) and a graph (FIG. 11D) displaying the estimated size of Ag nanoparticles calculated using ‘Image J’ software.

Referring to (d) of FIG. 6 and FIGS. 7 to 11, (d) of FIG. 6 illustrates two absorbance spectra: one for the blended semiconductor film and the other for the TDL film containing the FG.

The semiconductor film exhibits an absorption range spanning from visible light to near-infrared (NIR) wavelengths (400-1000 nm), whereas the TDL containing the FG displays the characteristic localized surface plasmon absorption of Ag particles (400-800 nm). The presence of Ag nanoparticles within the FG was confirmed through high-resolution transmission electron microscopy (HR-TEM).

(e) of FIG. 6 and FIG. 8 show HR-TEM images of Ag nanoparticles formed on the TDL. The embedded Ag nanoparticle structure in the TDL was verified via X-ray photoelectron spectroscopy (XPS) depth profiling (FIG. 9). (f) of FIG. 6 and FIG. 10 display energy-dispersive spectroscopy (EDS) mapping images of carbon and Ag, confirming the elemental composition corresponding to the particulate form shown in the HR-TEM images.

The average particle size of the Ag nanoparticles was 69.5±10.9 nm², with a particle density of 3347 particles/μm², corresponding to a filling area of 63% ((g) of FIG. 6 and FIGS. 11A-11D).

The operating principle of the stretchable WORM memory transistor is summarized in the circuit diagrams ((h-j) of FIG. 6). The initial memory transistor (pl) exhibited typical p-type transistor characteristics, with the drain current (ID) indicating a “0” state at the read gate voltage (Vread) ((h) of FIG. 6). During the writing process, it is necessary to expose the semiconductor channel to light (hv) while applying a positive gate bias (+VG). This indicates that the memory transistor can only be written using dual stimuli, combining both electrical and optical inputs. Photogenerated electrons pass through the TDL to become trapped in the FG via Fowler-Nordheim (F-N) tunneling, while holes remain in the active layer, shifting the threshold voltage (Vth) (rl) positively. As a result, the drain current at Vread represents the “l” state.

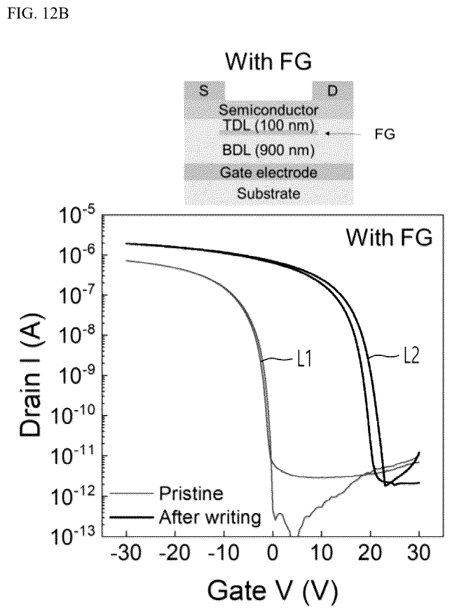

FIGS. 12A and 12B are graphs showing the transfer characteristics (VD=−10V) of a memory transistor without an FG (FIG. 12A) and a memory transistor with an FG (FIG. 12B).

L1 represents the transfer characteristics in the initial state (before writing).

L2 represents the transfer characteristics after writing (white light, 10 mW/cm², 50 VG, and 5 seconds).

The memory effect of the FG was confirmed by referring to a comparison with a conventional transistor without an FG (refer to FIGS. 12A and 12B).

The absence of hysteresis in the transfer curve of the memory transistor in this embodiment indicates that the memory phenomenon caused by electron trapping occurs within the FG, rather than at the interface between the semiconductor (nanoweb semiconductor layer (17)) and the TDL.

(i) of FIG. 6 illustrates a schematic of the real-time writing process for the memory transistor. Without light exposure, reverse (positive) or forward (negative) bias of VG did not affect the drain current (ID) at Vread. However, reverse bias under light exposure enabled WORM writing, resulting in an increase in ID (“l” state). The memory remained in the “on” state even after an erasing stimulus (light and forward gate bias).

Moreover, the intrinsically stretchable WORM memory was insensitive to deformation before and after writing (refer to (j) of FIG. 6). The constant ID under stretching, high memory on/off ratio, and long retention time are key features of the stretchable memory transistor.

### 4-2. Modulation and Operating Mechanism of the Memory Transistor

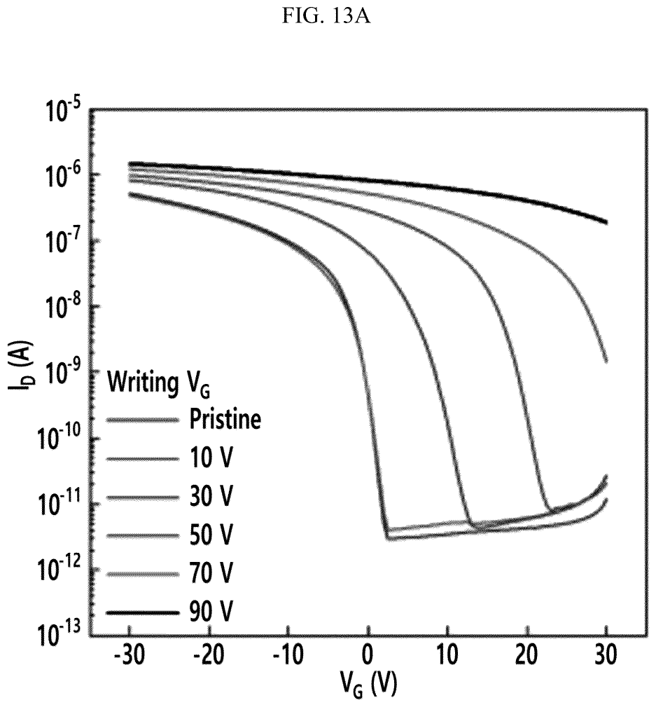

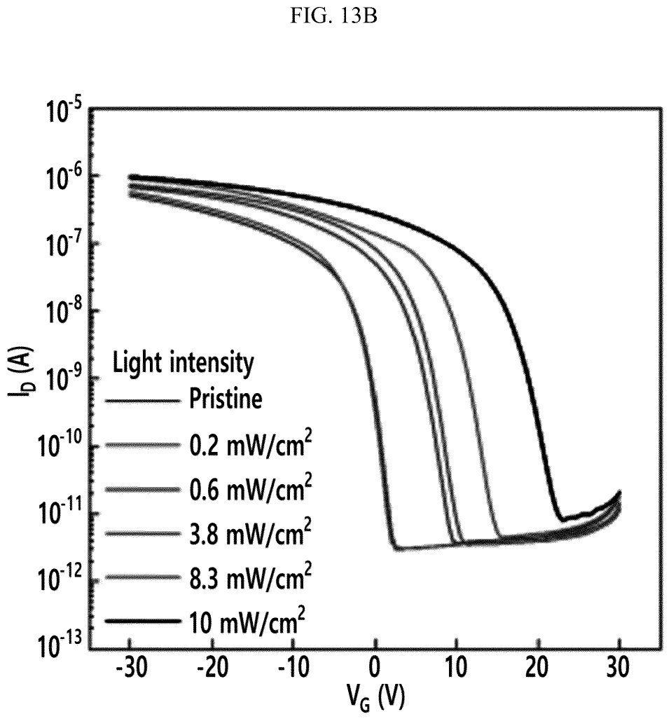

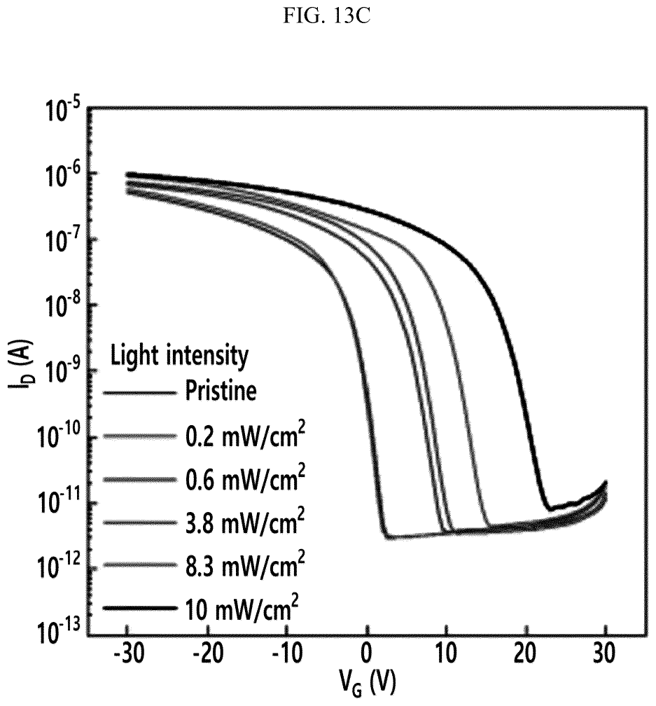

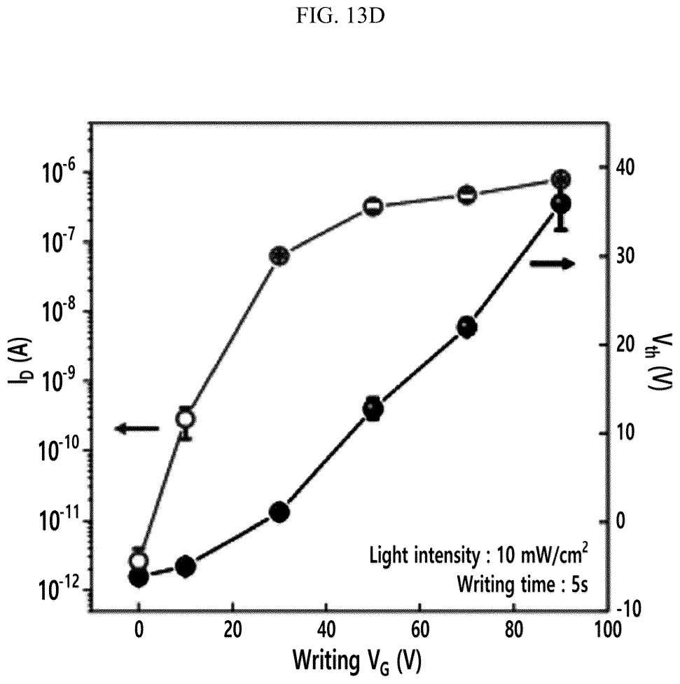

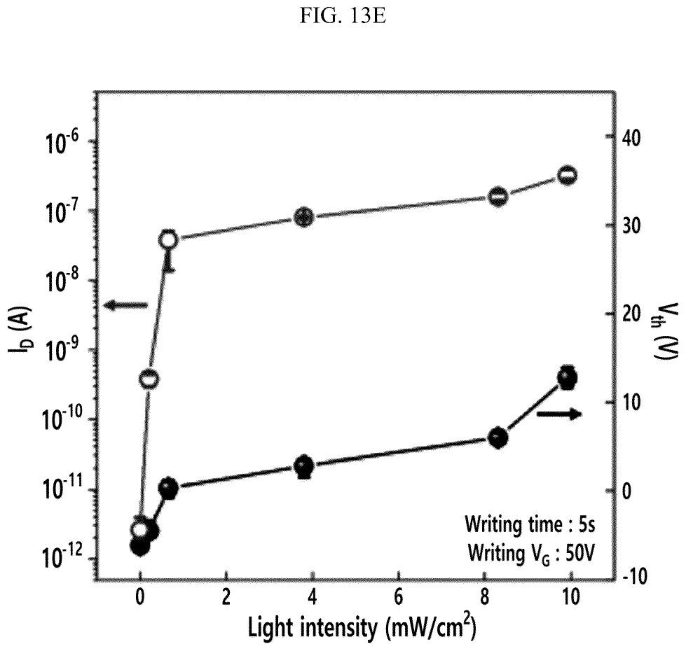

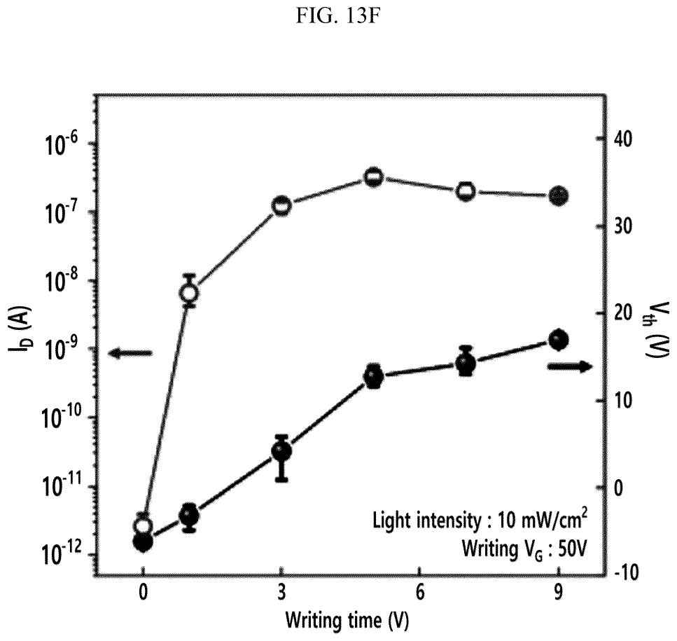

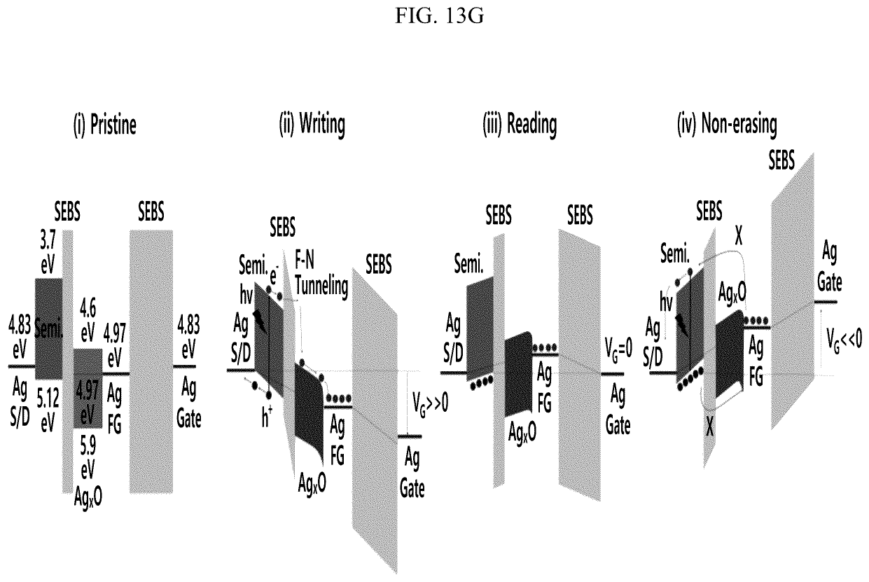

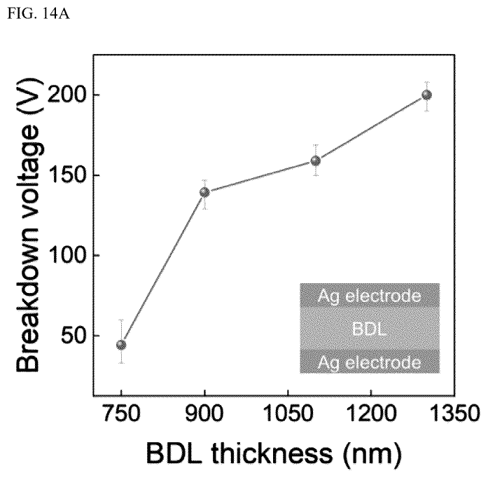

FIGS. 13A, 13B, and 13C are graphs showing the transfer characteristics during writing as functions of writing VG, white light intensity, and writing time, respectively, while keeping other factors constant.

FIGS. 13D, 13E, and 13F are graphs showing the changes in ID at VG=0V and Vth as functions of writing VG, white light intensity, and writing time, respectively.

FIG. 13G is a schematic band diagram illustrating the operating mechanism of the memory transistor in the experimental example.

The WORM memory characteristics of the FG memory transistor vary depending on three key parameters: writing VG, light intensity, and writing time.

At a fixed light intensity (10 mW/cm²) and writing time (5 seconds), an increase in writing VG caused the transfer curve to shift positively (FIGS. 13A and 13D). ID and Vth increased from their initial values (ID=10⁻¹² A and Vth=−6 V) to 8×10⁻⁷ A at VG=0 V (Vread) and 36 V, respectively.

At a constant writing voltage (VG=50 V) and writing time (5 seconds), increasing the light intensity resulted in a significant positive shift in Vth, accompanied by an increase in ID (3×10⁻⁷ A) at Vread (FIGS. 13B and 13E).

The shift in the transfer curve was measured as a function of writing voltage (VG=50 V) and light intensity (10 mW/cm²), providing a substantial memory window (ΔVth) and a large memory on/off ratio. The results showed that as the writing time increased, both ID and Vth grew linearly, reaching high values of 2×10⁻⁷ A and 17 V, respectively (FIGS. 13C and 13F).

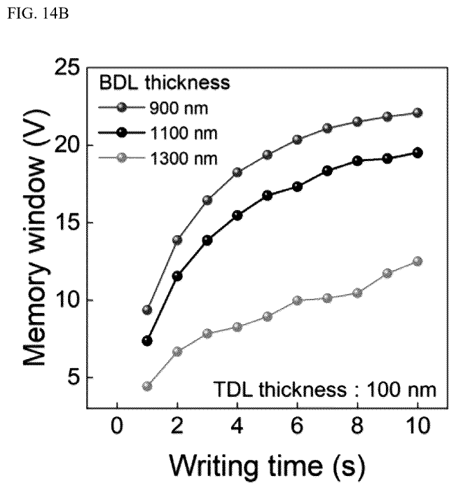

FIG. 14A is a graph showing the breakdown voltage of various BDL thicknesses in a metal-insulator-metal (MIM) structure.

FIG. 14B is a graph illustrating the memory window of a transistor under various BDL thicknesses, with constant thicknesses of FG (5 nm) and TDL (100 nm).

In this case, writing was performed using white light (10 mW/cm² for 5 seconds) and a writing VG (50 V) on a transistor optimized for the device's operating voltage, with a BDL thickness of 900 nm.

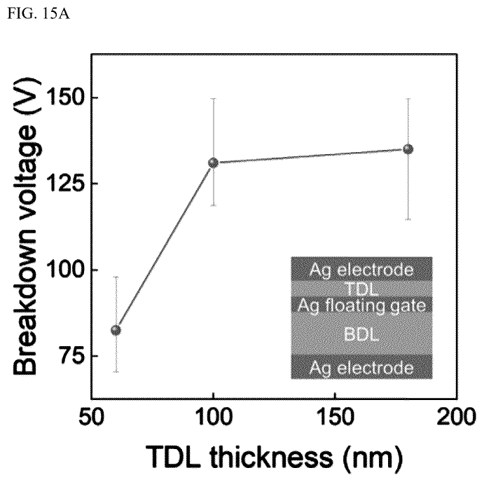

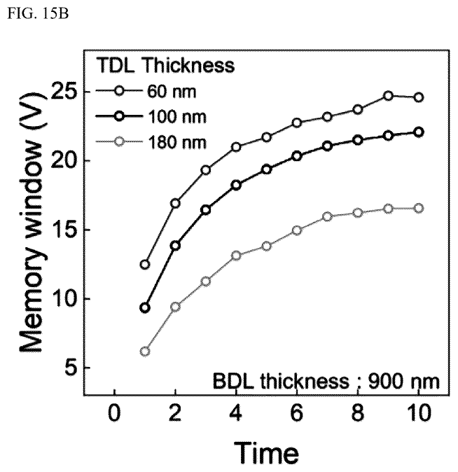

FIG. 15A is a graph depicting the breakdown voltage of the dielectric layer as a function of TDL thickness, with constant thicknesses of BDL (900 nm) and FG (5 nm) in the MIM structure.

FIG. 15B is a graph showing the memory window of a transistor under various TDL thicknesses, with constant thicknesses of FG (5 nm) and TDL (100 nm).

Here, writing was performed using white light (10 mW/cm² for 5 seconds) and a writing VG (50 V).

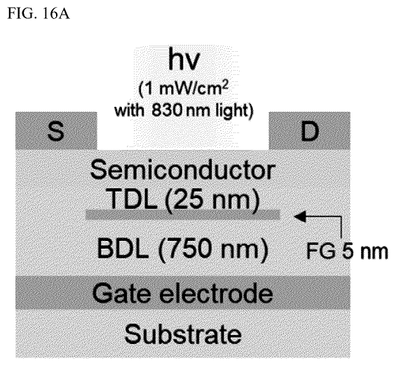

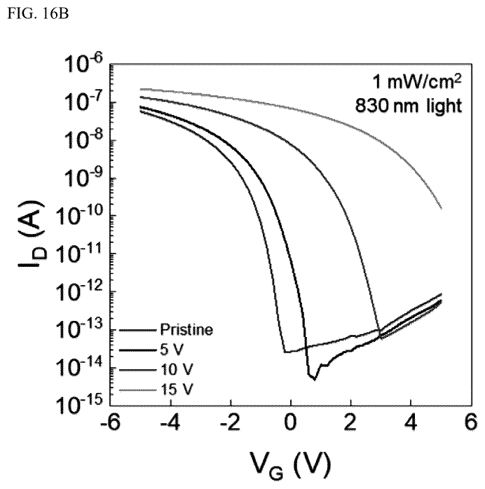

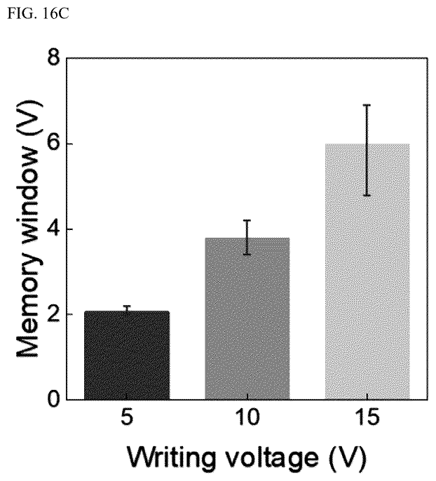

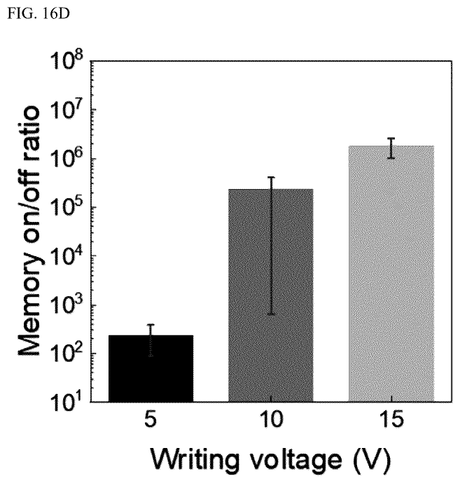

FIG. 16A is a cross-sectional diagram of a floating gate memory transistor designed for low-power operation using a thin dielectric layer.

FIG. 16B is a graph showing the transfer characteristics (VD=−5 V) as a function of writing voltage under 830 nm light (NIR, 1 mW/cm²).

FIG. 16C is a graph illustrating the memory window, and FIG. 16D is a graph showing the memory on/off ratio as a function of writing voltage (at VG=0 V).

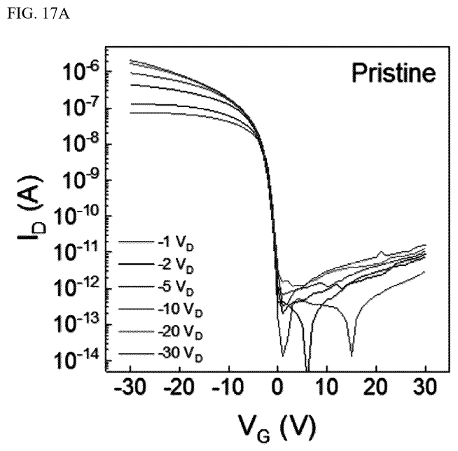

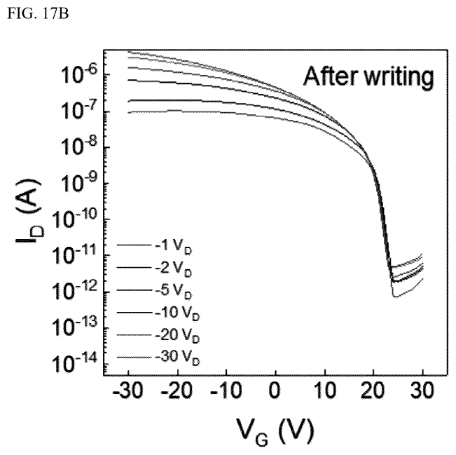

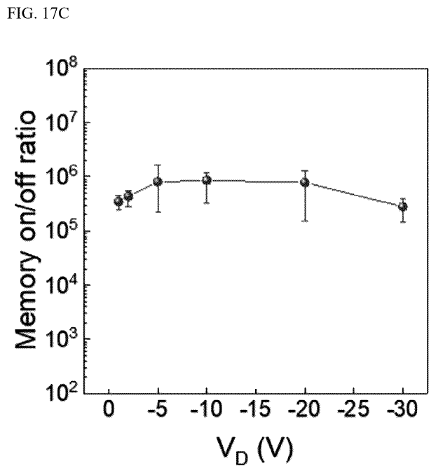

FIG. 17A is a graph showing the transfer characteristics (VD=−10 V) of the memory transistor in the pristine state, and FIG. 17B is a graph showing the transfer characteristics after writing (writing conditions: 50 VG, 5 seconds, and 10 mW/cm² under white light).

FIG. 17C is a graph illustrating the memory on/off ratio of the memory device (at VG=0 V).

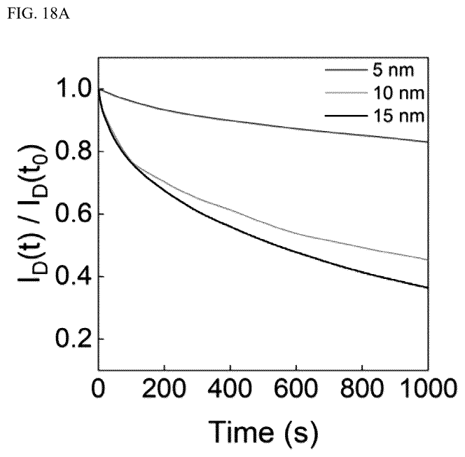

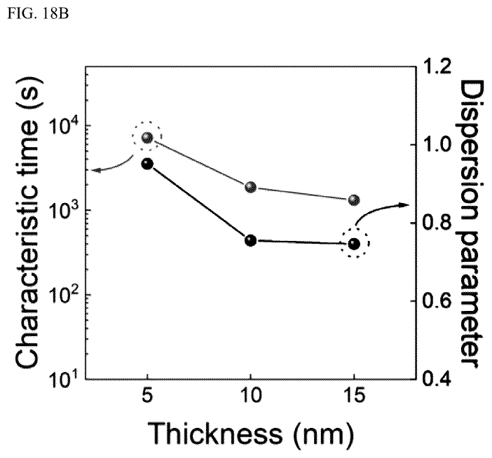

FIG. 18A is a graph showing the normalized drain current after the writing process (white light, 10 mW/cm², 50 VG, and 5 seconds) as a function of Ag FG thickness.

FIG. 18B is a graph illustrating the characteristic time (τ) and dispersion parameter (β) calculated from the normalized drain current using the mathematical equation (where τ is the characteristic time and β is the dispersion parameter).

Referring to FIGS. 13A-13G and 18A-18B, the embodiment implements a memory device with high breakdown voltage, wide memory window, and long retention time by finely adjusting the thicknesses of the BDL and TDL (refer to FIGS. 14A-14B and 15A-15B). By minimizing the thickness of the TDL (25 nm) and BDL (750 nm), memory could be written using low light intensity (1 mW/cm²) and low writing voltage (5 V) (refer to FIGS. 16A-16D). Additionally, it was observed that the device exhibited low dependency on drain voltage (VD) (refer to FIGS. 17A-17C).

The thickness of the Ag FG was related to the memory retention time, as densely packed Ag atoms can create leakage paths between adjacent Ag atoms. Therefore, the FG thickness was optimized to 5 nm, as shown in FIGS. 18A-18B.

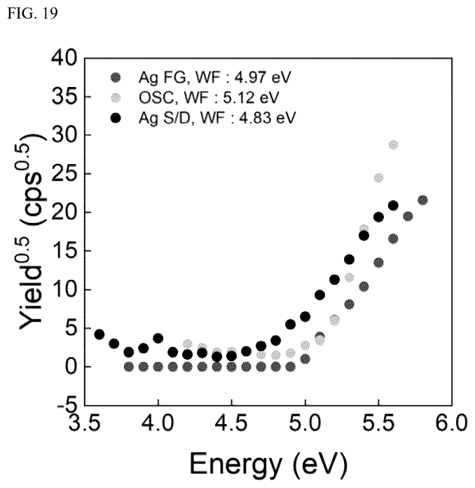

FIG. 19 is a graph showing the work functions of the Ag FG, OSC, and Ag S/D measured using PESA.

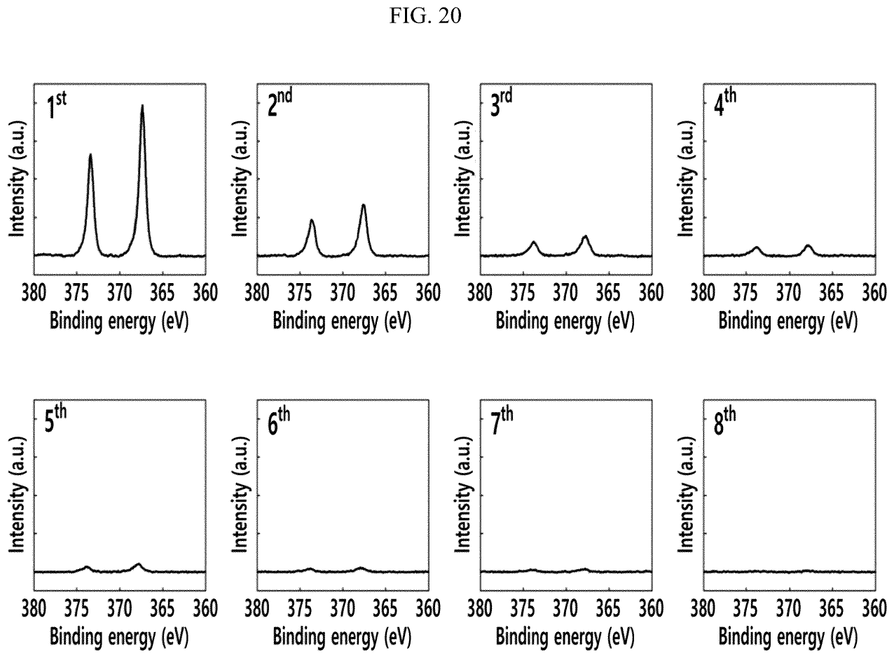

FIG. 20 is a graph displaying the XPS spectrum of the Ag 3d peak at various etching times, and FIG. 21 shows the XPS spectrum of silver (Ag) and silver oxide (AgxO) peaks at different etching times.

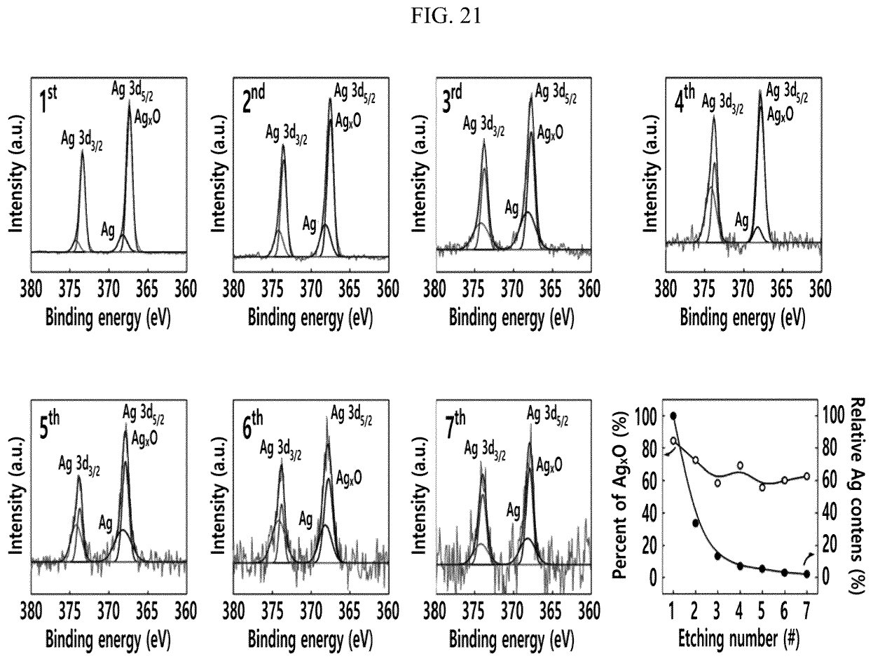

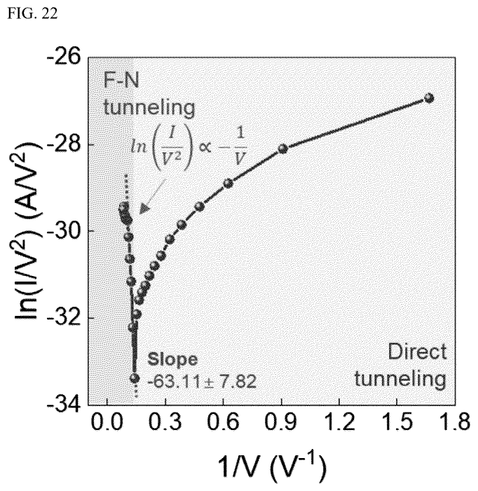

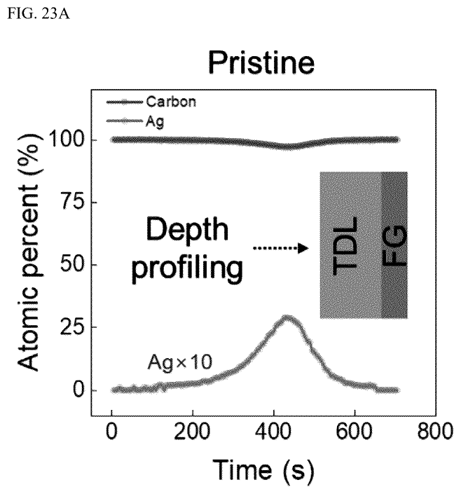

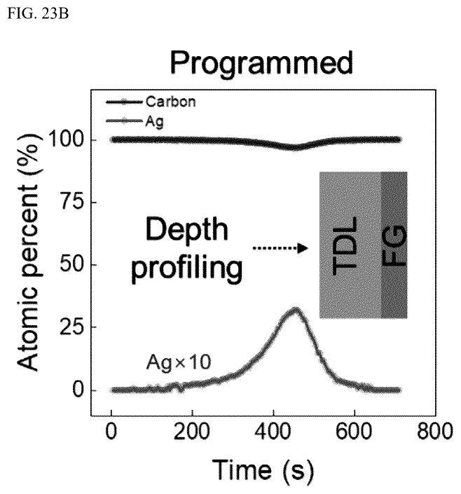

FIG. 22 illustrates current-voltage relationship of device for tunneling effect, and FIGS. 23A and 23B show the XPS depth profiles of the Ag-embedded tunneling dielectric layer (TDL) before programming (FIG. 23A) and after programming (FIG. 23B). In these figures, the Ag and carbon atoms represent the Ag floating gate and the TDL, respectively.

The operating mechanism of the memory transistor in the embodiment is described below.

The energy band diagram of the WORM memory transistor in its pristine state is shown in FIGS. 13G and 13I. The work functions, lowest unoccupied molecular orbital (LUMO), and highest occupied molecular orbital (HOMO) of all layers constituting the memory transistor were estimated using UV-Vis-NIR spectroscopy and photoelectron spectroscopy in air (PESA) data, combined with Tauc plots (refer to (d) of FIG. 6 and FIG. 19). The work functions of the Ag S/D electrode and the HOMO of the active semiconductor layer were 4.83 eV and 5.12 eV, respectively.

The work function of the Ag FG was measured to be 4.97 eV, which is higher than that of the thin-film Ag S/D electrode. This is attributed to the Ag FG being composed of Ag nanoparticles with sizes in the tens of nanometers (refer to (e) of FIG. 6).

The surface of the Ag nanoparticles embedded in SEBS easily forms a thin layer of AgxO oxide even at room temperature. The natural oxide layer on the surface of the embedded Ag nanoparticles was confirmed via X-ray photoelectron spectroscopy (XPS) (refer to FIGS. 20 and 21). Consequently, AgxO was included in the energy band diagram. The values for the conduction band minimum (CBM), Fermi level, and valence band maximum (VBM) were 4.97 eV, 4.6 eV, and 5.9 eV, respectively.

The writing process was carried out using both electrical and optical stimuli (refer to FIG. 13G (ii)). Under optical illumination, photocarriers (holes and electrons) were generated in the active semiconductor, and electrons in the LUMO band passed through the TDL via Fowler-Nordheim (F-N) tunneling, as inferred from the ln(I/V²) vs. (l/V) relationship of the device (refer to FIG. 22). Without forming Ag filaments, the electrons were strongly trapped in the FG under reverse gate bias (+VG), which was confirmed through XPS depth profiling (refer to FIGS. 23A-23B).

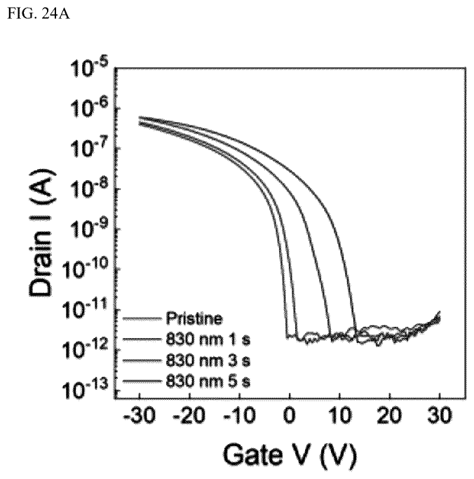

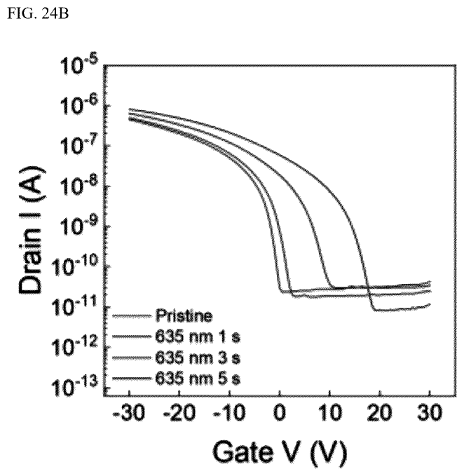

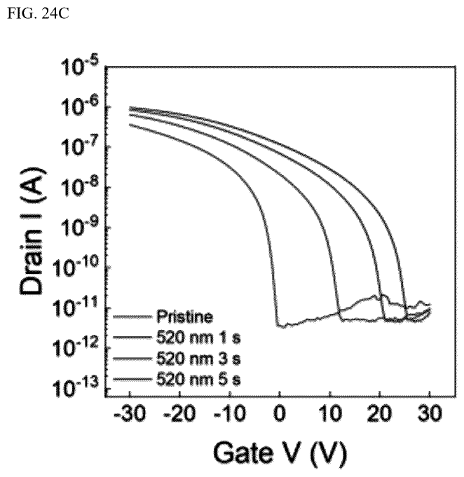

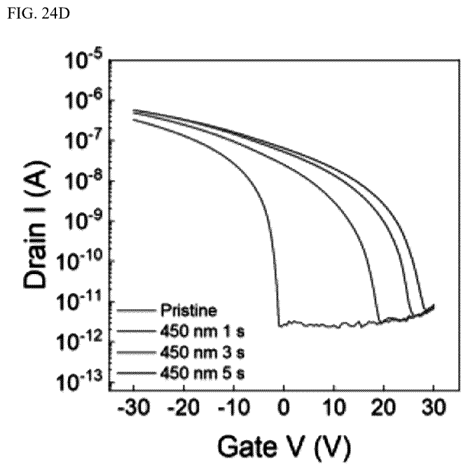

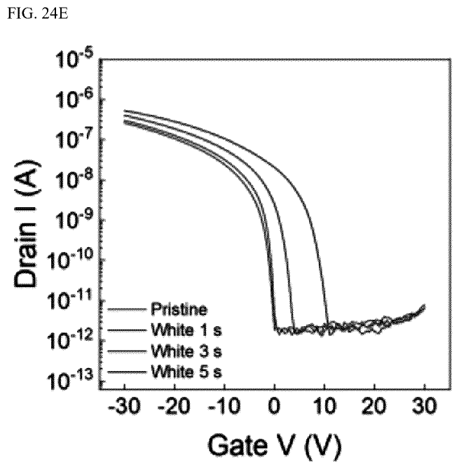

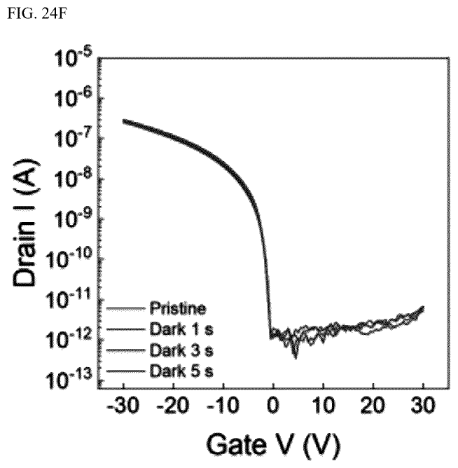

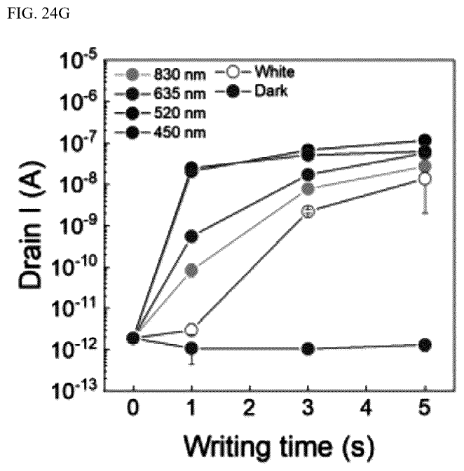

FIGS. 24A to 24G are graphs showing the transfer characteristics and changes in drain current of the memory transistor after the writing process under different light conditions.

Specifically:

FIGS. 24A to 24F illustrate the transfer characteristics (VD=−10 V) of the memory transistor after the writing process under various light conditions, including NIR (830 nm) (FIG. 24A), red (635 nm)(FIG. 24B), green (520 nm)(FIG. 24C), blue (450 nm)(FIG. 24D), white (FIG. 24E), and in the dark (FIG. 24F), with a writing voltage of 50 VG and light intensity of 4.5 mW/cm².

FIG. 24G shows the changes in drain current under different writing times and light conditions (at VG=0 V).

FIG. 24 presents the evaluation results of the writing characteristics of the device under illumination with light of wavelengths 450, 520, 635, and 830 nm to investigate the relationship between incident light wavelength and writing performance. The results indicate that the writing speed increases as the wavelength of light decreases. This is attributed to the fact that shorter wavelength light generates higher energy and produces a greater number of photocarriers per unit time in the DPPT-TT semiconductor, which has an absorption spectrum range of 400-1000 nm (see (d) of FIG. 6).

In the read state, holes induced in the semiconductor by the trapped electrons in the Ag FG caused an increase in ID at Vread (VG=0 V) (see (iii) of FIG. 13G). Erasure was performed by separating the electrons, where the trapped electrons were either emitted to the LUMO or recombined with photogenerated holes in the HOMO. However, the transistor maintained the read state even when exposed to light illumination and negative VG.

This persistence of the read state is due to additional energy barriers that hinder the detrapping process, which are intricately linked to the characteristics of the energy band structure (see (iv) of FIG. 13G). Furthermore, energy barriers due to the TDL and AgxO contribute to preventing photogenerated holes from moving into the Ag FG. These barriers require holes to overcome the energy difference between the HOMO of the semiconductor and the VBM (valence band maximum) of AgxO. Similarly, trapped electrons face a substantial energy barrier exceeding the difference between the CBM (conduction band minimum) of AgxO and the LUMO of the semiconductor. Before tunneling through the TDL, trapped electrons must overcome this barrier, making the transition from the Ag FG to the semiconductor extremely difficult.

Additionally, because the SEBS elastomer BDL has a low dielectric constant (2.2), it is challenging to generate a high electric field at the scale of several hundred nanometers (TDL thickness: 100 nm).

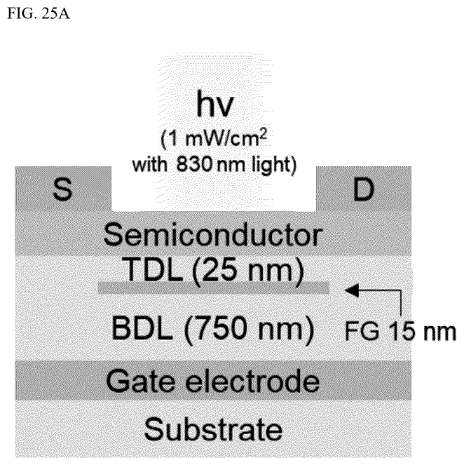

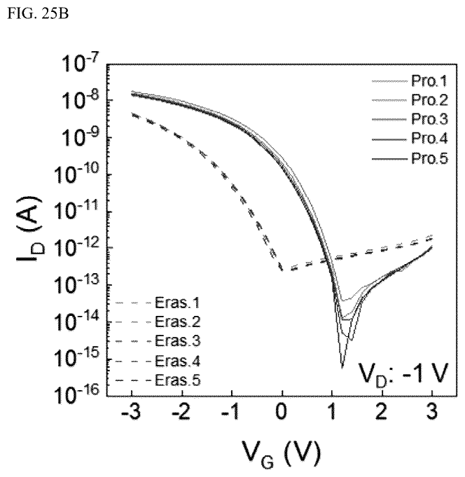

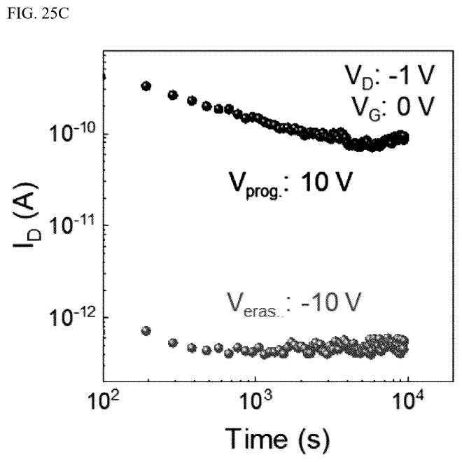

FIGS. 25A to 25D illustrate the writing, erasing, and retention characteristics of the memory transistor in the embodiment.

FIG. 25A is a schematic cross-sectional diagram of the stretchable floating gate memory transistor.

FIG. 25B is a graph showing the transfer curves of the memory transistor as a function of programming and erasing.

FIG. 25C is an electrical retention graph.

FIG. 25D is a graph showing the results of the programming/erasing (P/E) cycle test of the memory transistor.

By reducing the effective distance between the semiconductor (nanoweb semiconductor layer (17)) and the Ag FG (with TDL and FG thicknesses of 25 nm and 15 nm, respectively), trapping and detrapping processes were achieved, enabling both writing and erasing states (refer to FIGS. 25A and 25B). Considering the penetration depth of Ag particles into the TDL, the effective distance between the Ag particles and the semiconductor is less than 10 nm.

The transfer characteristics exhibited reversible changes in the threshold voltage, indicating that the memory transistor is rewritable. Despite a slight decrease in the initially programmed current, the memory transistor demonstrated stable retention results for up to 10⁴ seconds across 100 P/E cycles (refer to FIGS. 25C and 25D).

### 4-3. Stretchable Non-Volatile Memory Transistor

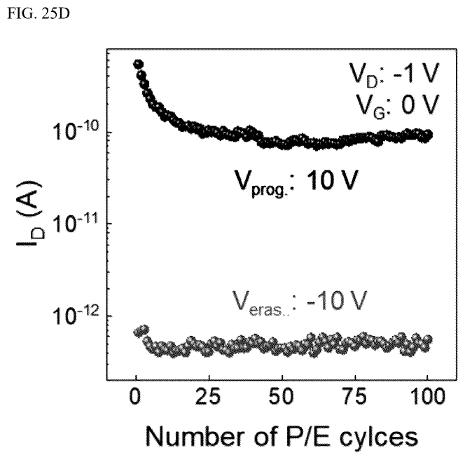

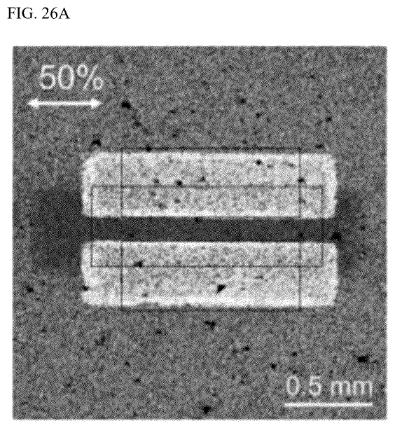

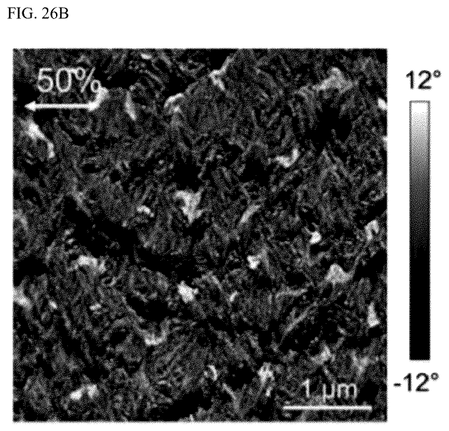

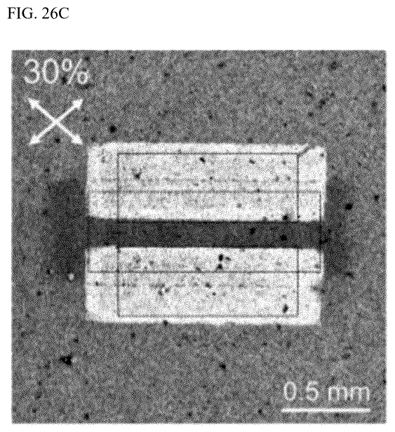

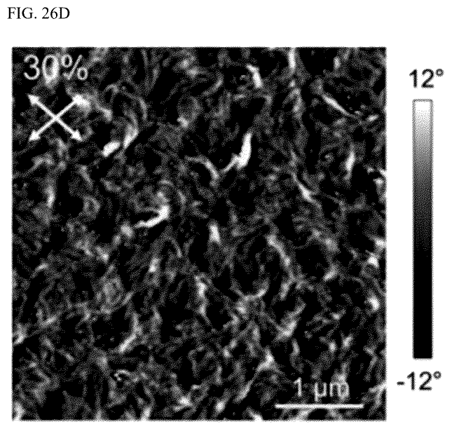

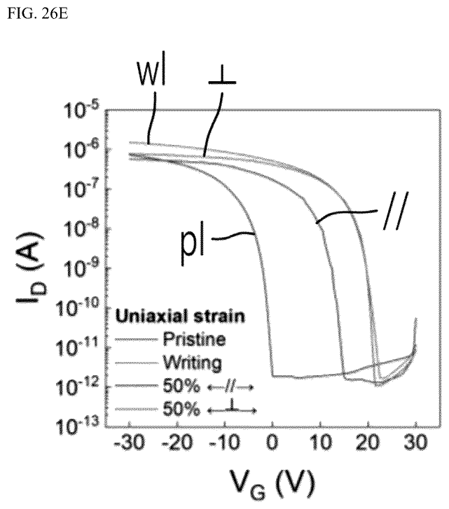

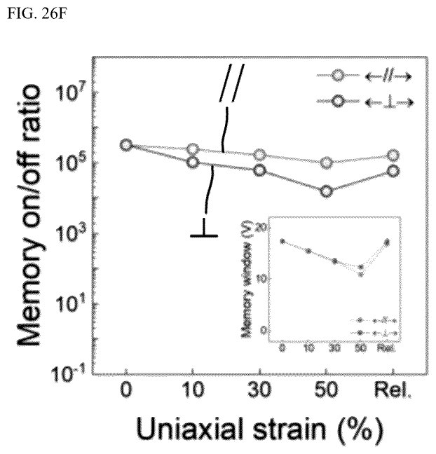

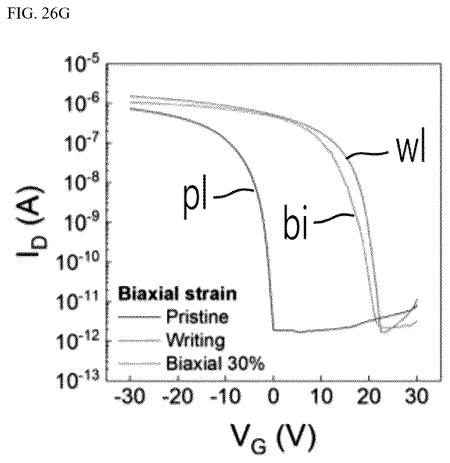

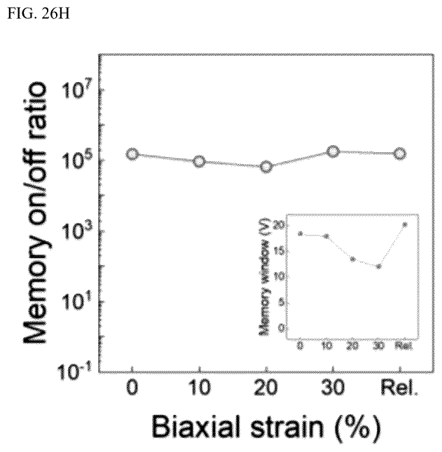

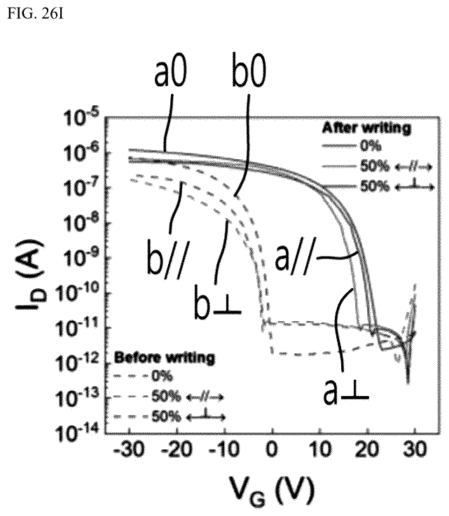

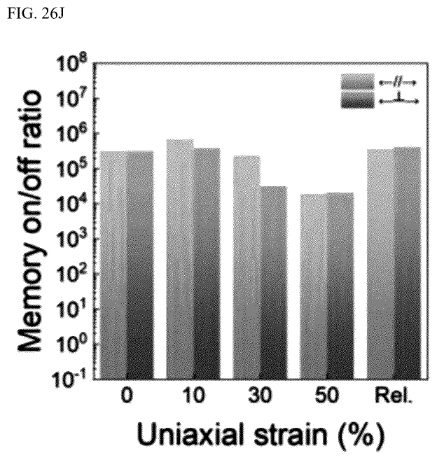

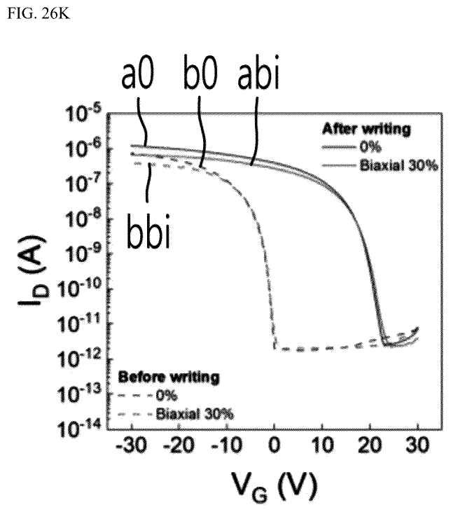

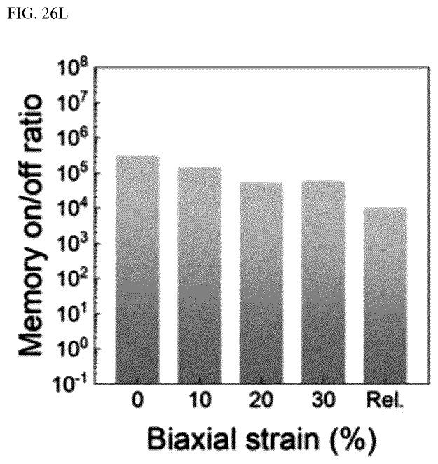

FIGS. 26A to 26I depict the physical and electrical characteristics of the stretchable non-volatile memory transistor featuring the stretchable floating gate layer used in the embodiment.

Specifically:

FIG. 26A shows the OM image of a single transistor unit.

FIG. 26B presents the AFM phase image of the semiconductor under 50% strain.

FIG. 26C illustrates the OM image of the transistor.

FIG. 26D displays the AFM phase image of the semiconductor under 30% biaxial strain.

FIG. 26E is a graph of the transfer curves under 50% uniaxial stretching.

FIG. 26F shows graphs of the memory on/off ratio and memory window (inset image) under various uniaxial stretching conditions during the write-stretch sequence.

FIG. 26G is a graph of the transfer curves under biaxial stretching.

FIG. 26H depicts graphs of the memory on/off ratio and memory window (inset image) under various biaxial stretching conditions during the write-stretch sequence.

FIG. 26I is a graph of the transfer curves under uniaxial stretching.

FIG. 26J shows the memory on/off ratio under various uniaxial stretching conditions during the stretch-write sequence.

FIG. 26K is a graph of the transfer curves under biaxial stretching.

FIG. 26L depicts the memory on/off ratio during the stretch-write sequence under various biaxial stretching conditions.

In FIGS. 26A-26L:

The arrows in FIGS. 26A and 26C indicate the stretching direction.

The dashed lines in FIGS. 26A and 26C represent the initial state of the transistor unit.

The “//” and “⊥” symbols denote the stretching directions parallel and perpendicular to the channel direction, respectively.

All writing processes were performed with a VG of 50 V, light intensity of 10 mW/cm², and white light exposure time of 5 seconds. The read drain and gate voltages were −10 V and 0 V, respectively.

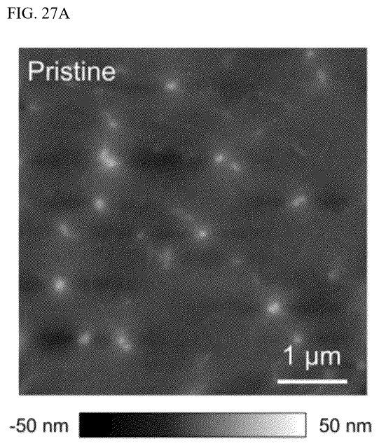

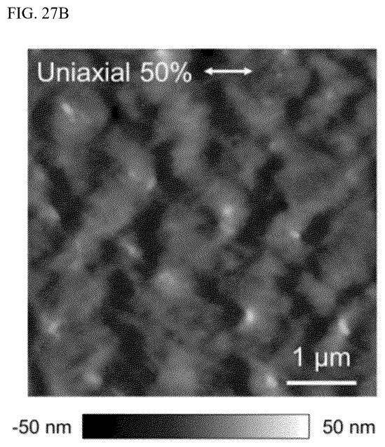

FIG. 27A shows AFM height images of the memory transistor in the pristine state, FIG. 27B under 50% uniaxial strain deformation, and FIG. 27C under 30% biaxial strain deformation.

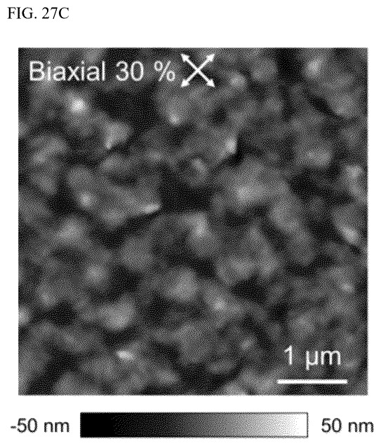

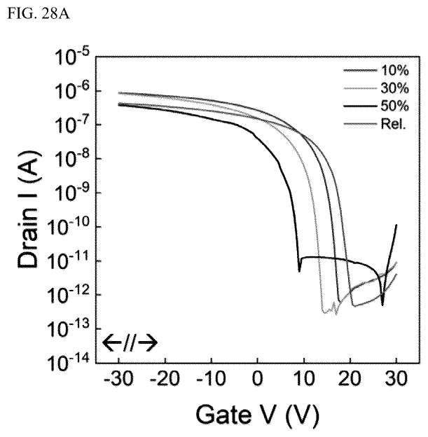

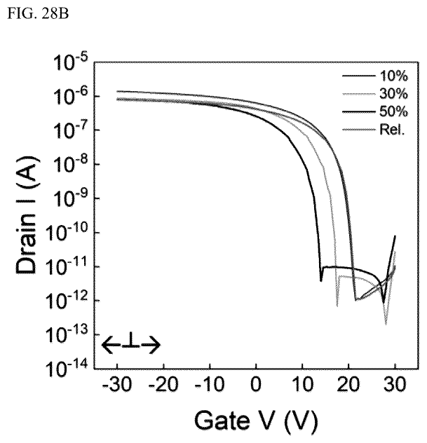

FIGS. 28A and 28B are graphs depicting the transfer characteristics (VD=−10 V) of the memory transistor as a function of the write-stretching sequence under uniaxial stretching deformation in the directions parallel (FIG. 28A) and perpendicular (FIG. 28B) to the channel.

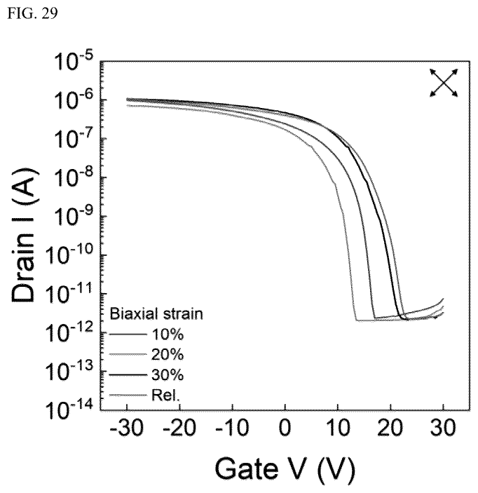

FIG. 29 is a graph illustrating the transfer characteristics (VD=−10 V) of the memory transistor as a function of the write-stretching sequence under biaxial strain deformation.

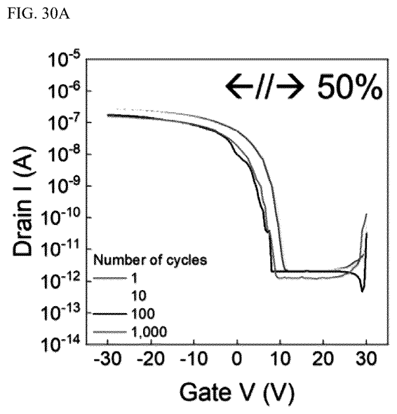

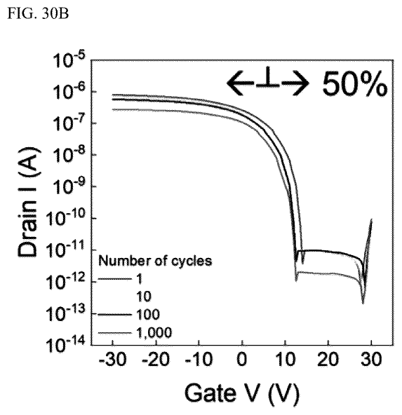

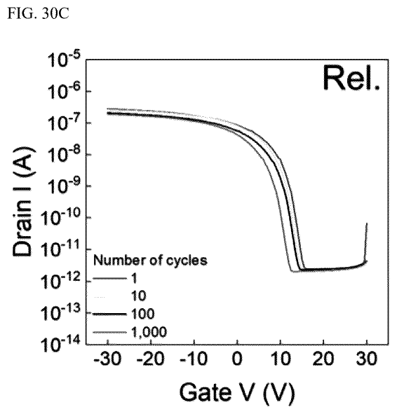

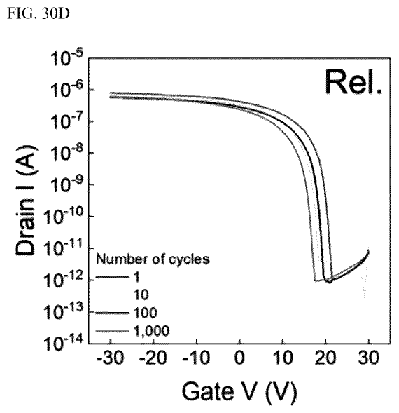

FIGS. 30A to 30D present the transfer characteristics (VD=−10 V) of the memory transistor programmed with the write-stretching sequence under 50% uniaxial stretching cycles, in the parallel direction (FIG. 30A), the perpendicular stretching direction under 50% strain (FIG. 30B), the parallel direction after releasing the strain (FIG. 30C), and the perpendicular stretching direction after releasing the strain (FIG. 30D).

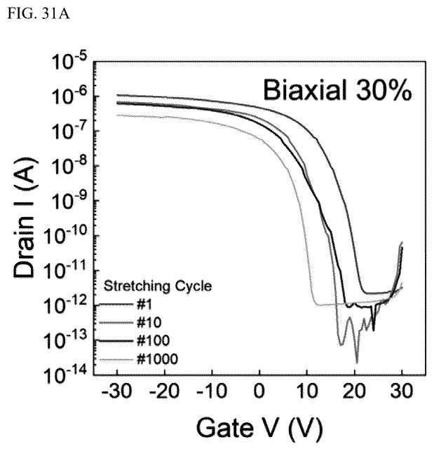

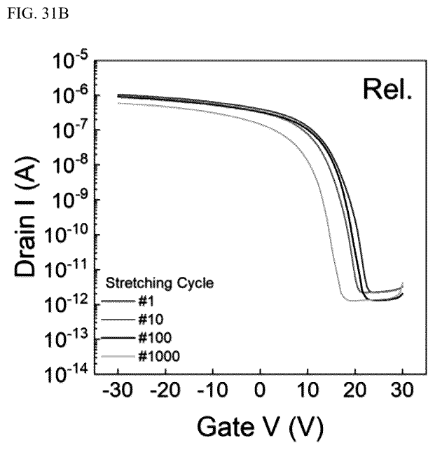

FIGS. 31A and 31B are graphs showing the transfer characteristics (VD=−10 V) of the memory transistor programmed with the write-stretching sequence under 30% biaxial stretching cycles (FIG. 31A) and after the strain was released (FIG. 31B).

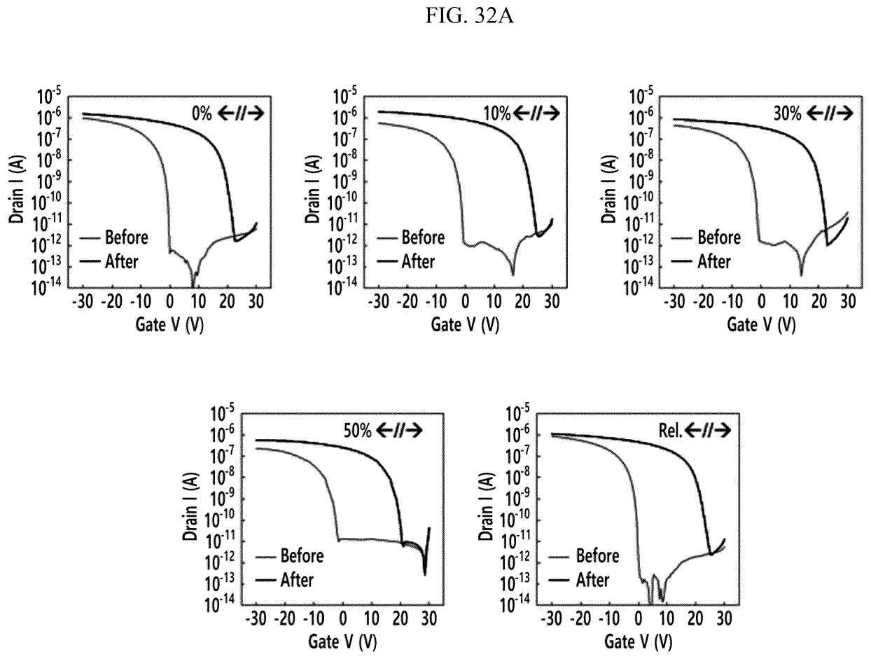

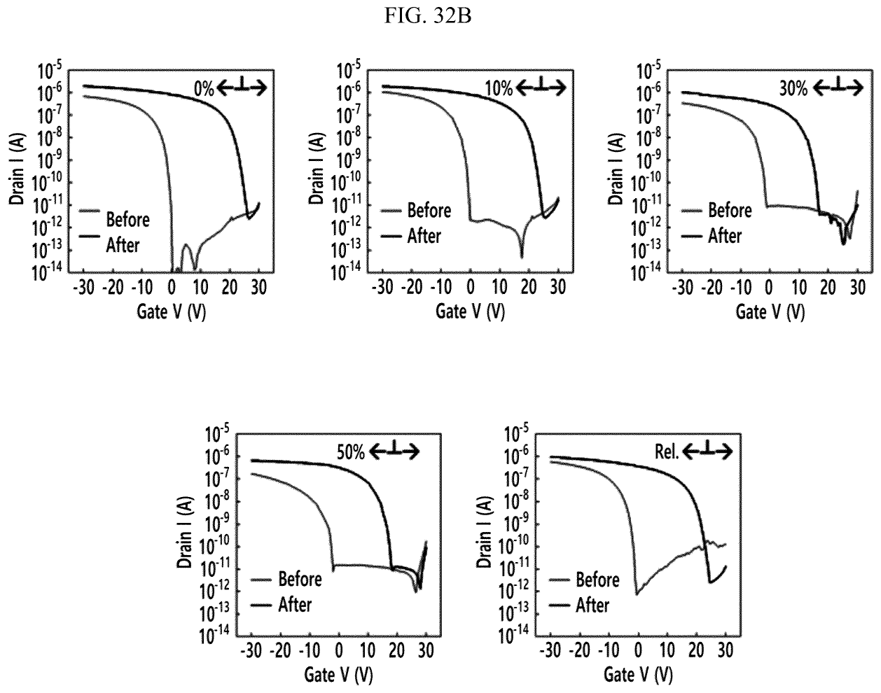

FIGS. 32A and 32B illustrate the transfer characteristics (VD=−10 V) of the memory transistor programmed with the stretch-writing sequence under uniaxial stretching in the directions parallel (FIG. 32A) and perpendicular (FIG. 32B) to the channel.

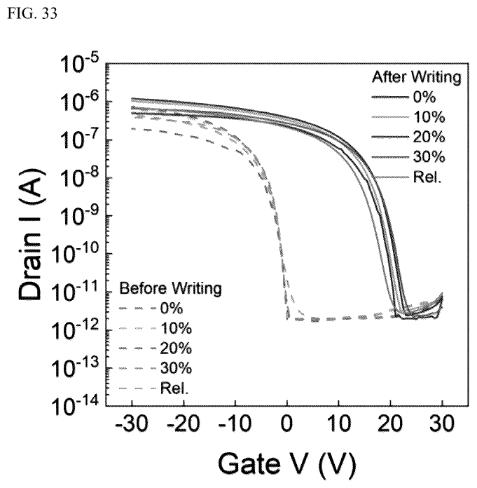

FIG. 33 is a graph showing the transfer characteristics (VD=−10 V) of the memory transistor programmed with the stretch-writing sequence under biaxial strain deformation.

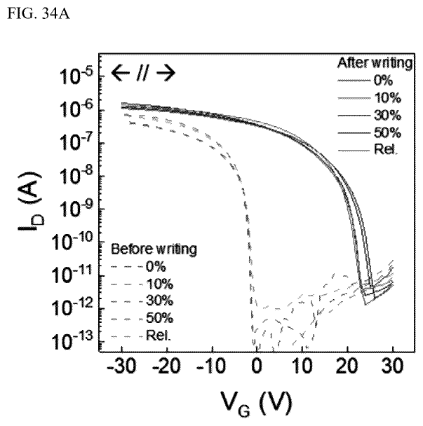

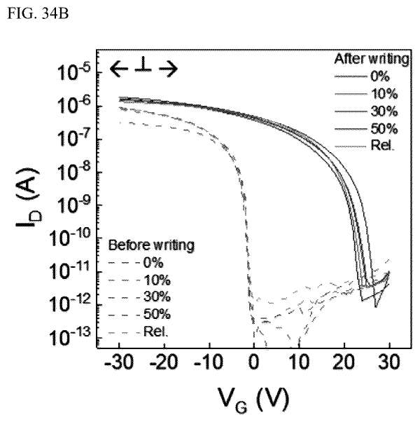

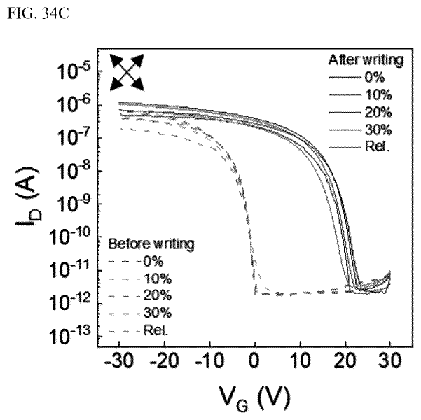

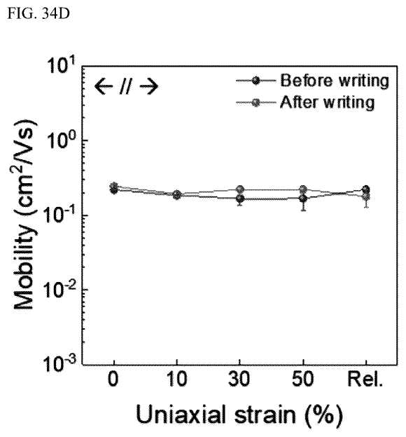

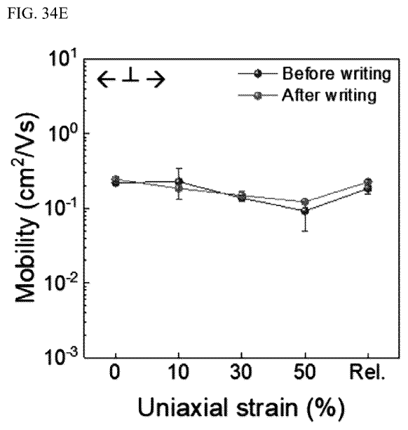

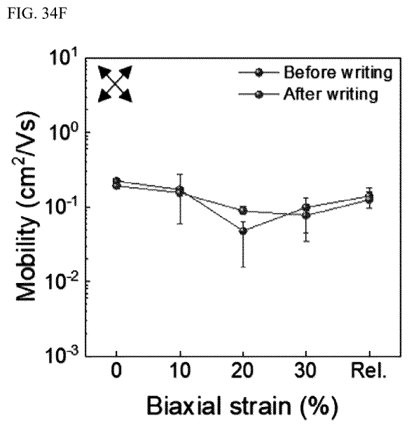

FIGS. 34A to 34D present graphs of the transfer characteristics (VD=−10 V) and field-effect mobility during the writing process (50 VG, 5 s, 10 mW/cm² white light) under various stretching directions relative to the channel: parallel (FIGS. 34A and 34D), perpendicular (FIGS. 34B and 34E), and biaxial stretching (FIGS. 34C and 34F).

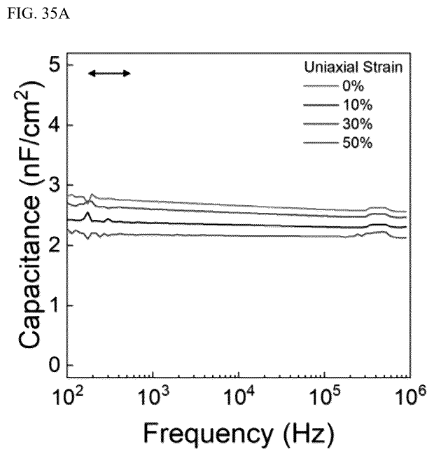

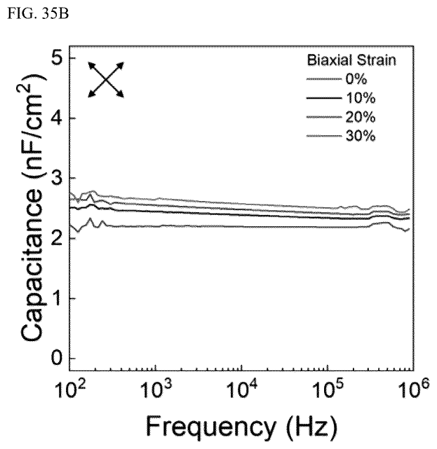

FIGS. 35A and 35B are graphs showing the frequency-capacitance characteristics of the dielectric material in the memory transistor (Ag electrode/TDL/FG/BDL/Ag electrode) under uniaxial (FIG. 35A) and biaxial (FIG. 35B) strain deformation.

To ensure seamless and stable integration of the e-skin memory transistor with human skin, it is essential to guarantee a minimum stretchability of 30%, corresponding to the elastic limit of human skin.

FIGS. 26A and 26B show the OM and AFM phase images of the stretched memory transistor, illustrating its micro- and nanoscale morphology. Due to the inherently stretchable components of the transistor, it demonstrated the ability to elastically deform under high strain of up to 50% without mechanical failure (FIG. 27). Additionally, the device underwent elastic area expansion under 30% biaxial strain without mechanical rupture (FIGS. 26C and 26D). The solid lines forming crossed rectangles in the OM image represent the initial shape of the memory transistor before deformation.

To investigate memory operation insensitivity to strain, the performance changes of the device under strain were measured in two scenarios involving different writing and stretching sequences.

In the first scenario, memory was written and then stretched (write-stretching)(FIG. 26E).

In the second scenario, the device was stretched and then written in the strained state (stretch-writing) (FIGS. 26I to 26L).

In the pristine state (pl, FIG. 26E), the device exhibited typical p-type transfer characteristics. In contrast, after writing, a significant positive shift was observed in the transfer curve (wl). Both Vth and ID increased, reaching approximately 18 V and 10⁻⁶ A, respectively.

The memory on/off ratio in the initial writing state remained practically unchanged under uniaxial strain of up to 50%, regardless of the stretching direction (parallel or perpendicular to the current path) (FIGS. 26E, 26F, and 28).

The memory on/off ratio also remained consistent after the release of biaxial strain, even under 30% area expansion (FIGS. 26G, 26H, and 29).

It was observed that the Vth in the pristine state remained above 10 V under both uniaxial and biaxial deformation. Furthermore, the memory transistor in the embodiment demonstrated excellent durability during repeated stretching for up to 1000 cycles at 50% uniaxial or 30% biaxial strain (FIGS. 30A-31B).

In the second scenario of the stretch-writing sequence, the writing performance of the device was measured under uniaxial and biaxial deformation. Under all investigated stretching conditions, the writing-related transfer curves of the device exhibited nearly identical shifts, with a positive shift in Vth and a substantial increase in ID.

Even under up to 50% uniaxial strain and 30% biaxial strain, the device demonstrated a memory window greater than 10 V and a memory on/off ratio exceeding 10.

The field-effect mobility of the memory transistor remained unchanged in magnitude after deformation following writing (FIGS. 34A-34F). Modified factors such as the dielectric capacitance and channel size under various deformations are summarized in FIGS. 35A-35B and Table 1.

TABLE 1
Changes in Geometry and Capacitance
of the Deformed Memory Transistor

| | | Channel | Channel | |
|---|---|---|---|---|
| | Strain | length | width | Capacitance* |
| Stretching direction | (%) | (μm) | (μm) | (nF/cm²) |
| Parallel stretching | 0 | 151 | 998 | 2.18 |
| to channel | 10 | 158 | 953 | 2.38 |
| (←//→) | 30 | 202 | 857 | 2.60 |
| | 50 | 237 | 800 | 2.73 |
| | Rel. | 153 | 975 | 2.18 |
| Perpendicular | 0 | 151 | 998 | 2.18 |
| stretching to channel | 10 | 144 | 1018 | 2.38 |
| (←⊥→) | 30 | 139 | 1218 | 2.60 |
| | 50 | 130 | 1413 | 2.73 |
| | Rel | 152 | 1003 | 2.18 |
| Biaxial stretching | 0 | 150 | 1000 | 2.18 |
| (×) | 10 | 176 | 1032 | 2.45 |
| | 20 | 188 | 1090 | 2.54 |
| | 30 | 199 | 1148 | 2.67 |
| | Rel. | 153 | 1004 | 2.18 |

*Capacitance at 1 kHz.

### 4-4. Reliability of the Stretchable Memory Transistor

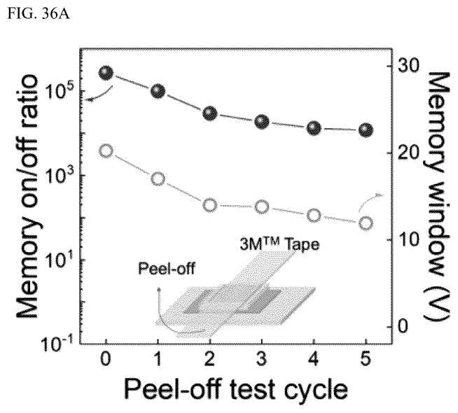

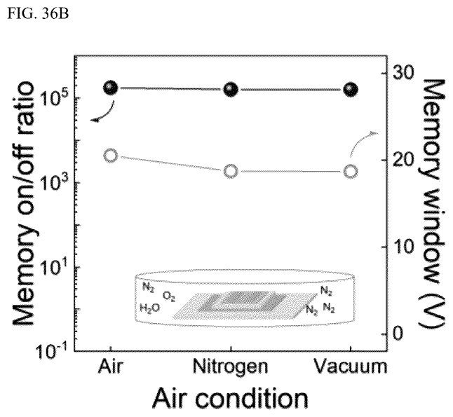

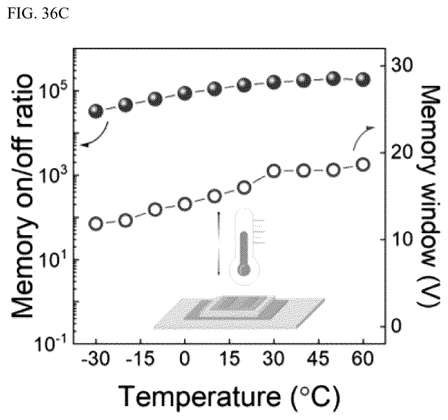

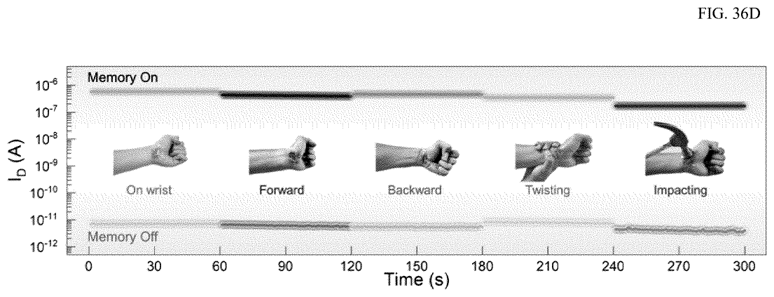

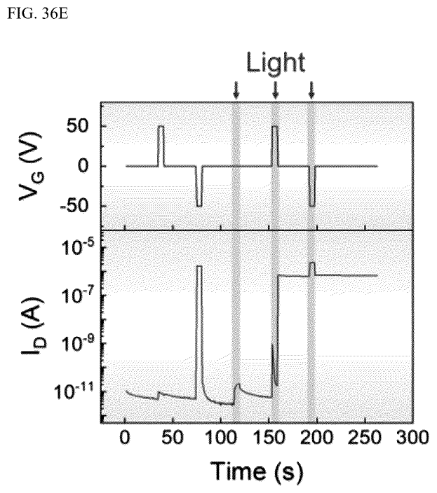

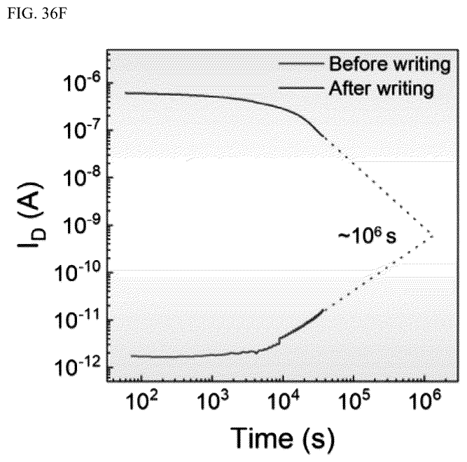

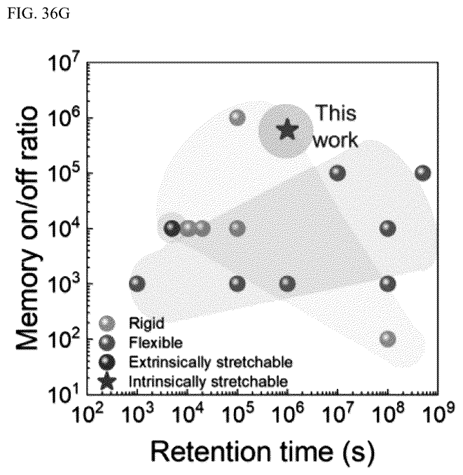

FIGS. 36A to 36G depict the reliability evaluation results of the stretchable memory transistor.

FIG. 36A illustrates changes in the memory on/off ratio during testing under peel-off cycles.

FIG. 36B shows changes in the memory on/off ratio under ambient environmental conditions.

FIG. 36C displays changes in the memory on/off ratio under varying ambient temperature conditions.

FIG. 36D presents the real-time drain current changes before and after writing on the memory device during wrist movements, including forward, backward, twisting, and tapping actions, while worn on a human wrist. All writing processes were performed using a gate voltage of 50 V, a light intensity of 10 mW/cm², and 5 seconds of white light exposure.

FIG. 36E is a graph illustrating the real-time writing process under varying gate voltage and light exposure conditions.

FIG. 36F depicts the retention characteristics of the memory device with WORM properties.

FIG. 36G is a graph comparing the performance of the memory device in this embodiment with conventional memory devices, showing a plot of the memory on/off ratio as a function of retention time.

The read drain and gate voltages were −10 V and 0 V, respectively.

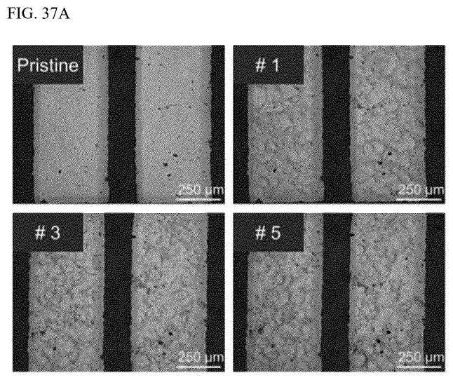

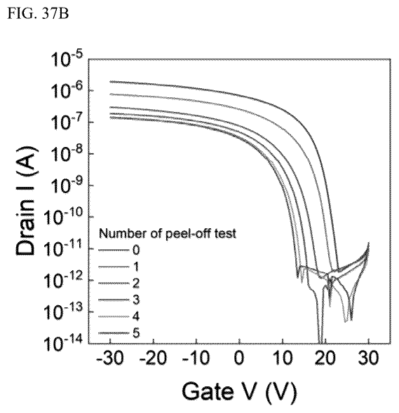

FIGS. 37A and 37B depict the OM image (FIG. 37A) and transfer characteristics (VD=−10 V) (FIG. 37B) of the memory transistor after the writing process during a peel-off cycle test using 3M Tape™ (Model: Magic Tape 810, adhesive strength: 2.2 N/cm).

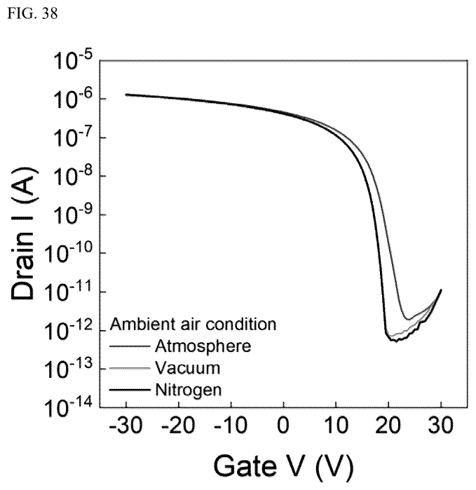

FIG. 38 is a graph showing the transfer characteristics (VD=−10 V) of the memory transistor in the embodiment after the writing process under various ambient air conditions.

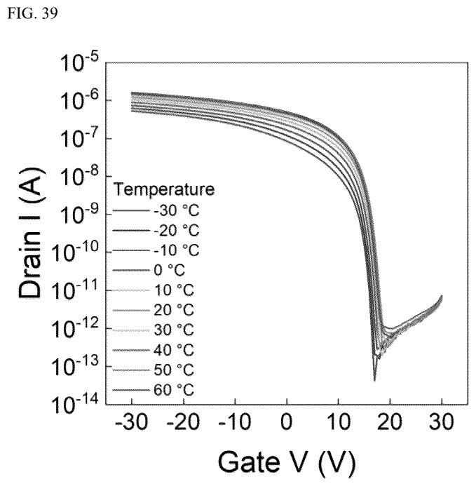

FIG. 39 is a graph illustrating the transfer characteristics (VD=−10 V) of the memory transistor in the embodiment after the writing process at various temperatures.

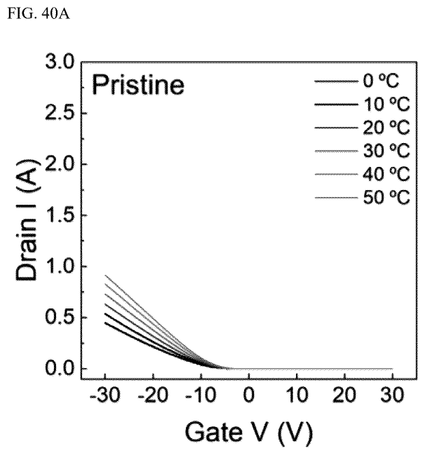

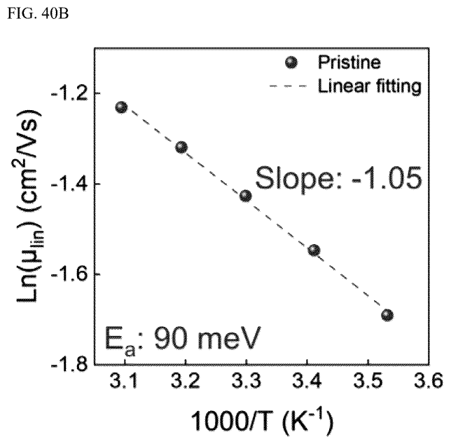

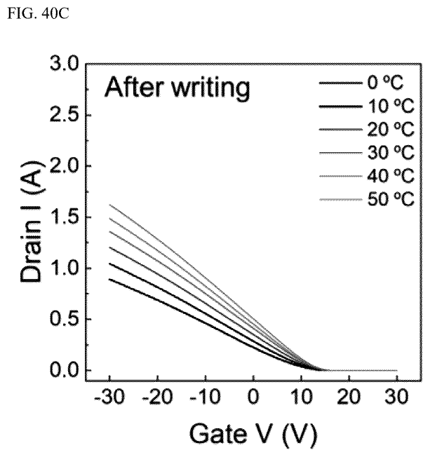

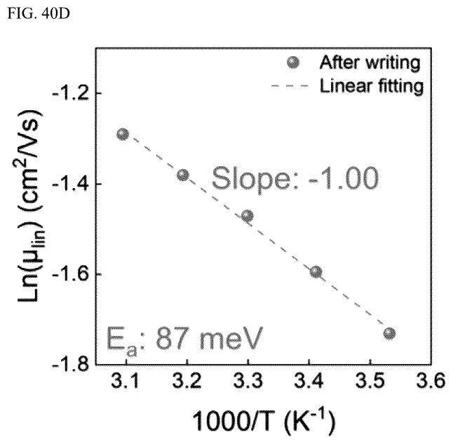

FIGS. 40A to 40D show the transfer characteristic curves for calculating activation energy before (FIG. 40A) and after (FIG. 40C) the writing process at various temperatures, as well as the Arrhenius plots calculated using the equation μ=μ₀ exp(−Ea/KBT) (where μ is mobility, KB is the Boltzmann constant, and T is the absolute temperature) for the pristine state (FIG. 40B) and after writing (FIG. 40D).

As shown in FIGS. 40A to 40D, the activation energy values before and after writing are similar, indicating the absence of interface traps during the writing process and the consistent performance of the memory transistor.

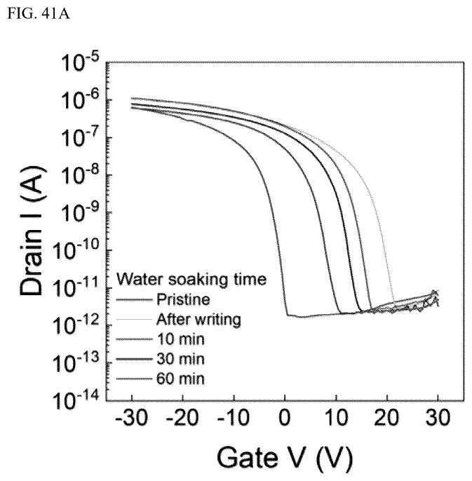

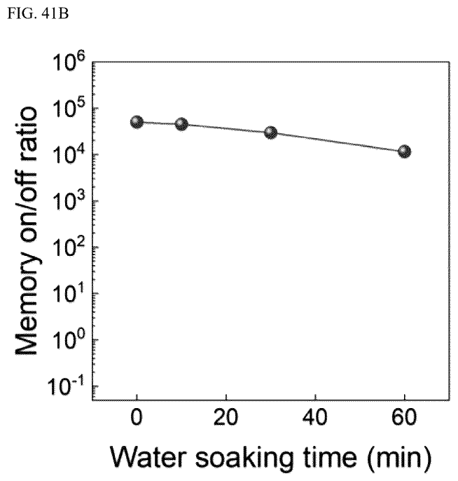

FIGS. 41A and 41B depict the transfer characteristics (VD=−10 V) (FIG. 41A) and the memory on/off ratio (FIG. 41B) of the memory transistor in the embodiment during wafer soaking times.

Environmental stability, which is essential for applying WORM memory to wearable devices, was evaluated through peel-off, ambient gas, temperature, and humidity tests.

The peel-off stability of the memory transistor in the embodiment after writing was investigated using a peel-off test with 3M™ Tape (adhesive strength: 2.2 N/cm) (FIGS. 36A and 37). Even after five peel-off cycles, the device maintained a memory on/off ratio exceeding 10⁴ and a memory window greater than 10 V. This performance is primarily attributed to the high adhesive strength at all interfaces of the device (S/D electrode/semiconductor/dielectric/gate electrode/substrate), which is due to the adhesive properties of the Ag-elastomer blended layer and SEBS.

The operational stability of the memory transistor in the embodiment was evaluated under various ambient conditions, including air, nitrogen, and vacuum (2×10² torr) (FIGS. 36B and 38). The memory on/off ratio and memory window of the device in the embodiment remained nearly unchanged under all investigated ambient conditions.

Additionally, the memory transistor in the embodiment demonstrated stable memory performance, maintaining a memory on/off ratio exceeding 10⁴ and a memory window greater than 10 V across a temperature range of −30° C. to 60° C., which represents seasonal temperature fluctuations. The device exhibited no change in activation energy required for writing across this temperature range (FIGS. 36C, 39, and 40A-40D).

Finally, the waterproof performance of the memory transistor in the embodiment was confirmed as it operated normally even after being submerged in water for 60 minutes. Critical properties for skin-mounted devices, such as a memory on/off ratio (>10⁴) and a memory window (>10 V), were maintained (FIGS. 41A-41B).

E-skin devices integrated into human skin must operate stably despite irregular deformations caused by body movements. To simulate such scenarios, the memory device was attached to a human wrist, and the memory on/off ratio was measured under various deformations. The on/off drain current values of the memory device remained nearly constant, even during four types of real-time deformations experienced while worn on a wrist (FIG. 36D).

Additionally, the real-time operation of the memory device was monitored under certain combinations of electrical and optical stimuli (FIG. 36E). The device exhibited typical transistor switching behavior as a function of reverse (VG=50 V, 5 seconds) and forward (VG=−50 V, 5 seconds) gate biases in the absence of light. When exposed to light alone, ID slightly increased due to photocarriers in the active semiconductor layer. When both light and reverse (positive) gate bias were applied, electrons tunneled and were trapped in the FG, significantly increasing the memory on/off ratio to over 10⁴. This written state persisted even under light exposure and forward gate bias.

The memory transistor with an optimized FG thickness in the embodiment exhibited a high memory on/off ratio (6×10⁵) and long retention time (10⁶ seconds) (FIG. 36F), supported by the estimated retention characteristic time (FIG. 18).

In terms of data storage lifespan, long memory retention is crucial for memory devices.

FIG. 36G shows a comparison between our device and previously reported organic memory transistors, including rigid, flexible, and stretchable devices. Specifically, the memory on/off ratio and retention time were compared, as summarized in Table 2.

TABLE 2
Device Performance Comparison.

| | Charge | | Retention | On/off | V_{C} @ | | |
|---|---|---|---|---|---|---|---|
| | trapping | | time | current | Program/ | Mechanical | |
| Semiconductor | layer | Dielectric | (s) | ratio | erase | property | Reference |
| DPPT- | Ag | SEBS/SEBS | 10⁶ | 6 × 10⁵ | +/−70 V & | Intrinsically | This |
| TT:SEBS | nanoparticles | (100 nm TDL) | | | 10 mW/cm² | stretchable | work |
| | | SEBS/SEBS | >10⁴ | >10² | +/−10 V | | |
| | | (25 nm TDL) | | | 1 mW/cm² | | |
| P(NDI2OD-T2) | Au | PS/PMMA | 10⁷ | 10⁵ | +/−70 V | Flexible | Ref. 1 |
| P3HT | Cu | P(VDF-TrFe)/PS | 10⁸ | 10³ | +/−60 V | Flexible | Ref. 2 |
| Pentacene | CuFe₂O₄ | Al₂O₅ | 10³ | 10³ | +/−20 V | Flexible | Ref. 3 |
| PDPP-TBT | Au | Al₂O₃ | 10⁶ | 10³ | +/−40 V | Flexible | Ref. 4 |
| Pentacene | Au | Al₂O₅ | 10⁵ | 10³ | +/−3 V | Flexible | Ref. 5 |
| C₆₀ | Al | pV3D3/pEGDMA | 10⁸ | 10⁴ | +/−10 V | Flexible | Ref. 6 |
| Pentacene | pV3D3 | pBDDA | 10⁸ | 10⁵ | +/−14 V | Flexible | Ref. 7 |
| Pentacene | WG₅/TMP | SiO₂ | 10⁵ | 10⁴ | −100 V, | Rigid | Ref. 8 |
| | | | | | 5 mW/cm2 | | |
| Pentacene | Au | PMMA/PEs | 10⁵ | 10⁵ | +/−80 V | Rigid | Ref. 9 |
| Pentacene | PCBM/PMMA | SiO₂ | 10⁴ | 10⁴ | −60 V, | Rigid | Ref. 10 |
| | | | | | 3 mW/cm2 | | |
| Pentacene | PS/DPP | SiO₂ | 10⁴ | 10⁴ | −100 V, | Rigid | Ref. 11 |
| | | | | | 20 V + | | |
| | | | | | 188 mW/cm2 | | |
| Pentacene | C₆₀/TTC | P(VDF-TrFE- | 10⁸ | 10² | +/−40 V | Rigid | Ref. 12 |
| | | CFE) | | | | | |
| Pentacene | PS/CsPbBr₃ | Al₂O₃ | 2 × 10⁴ | 10⁴ | +/−5 V | Rigid | Ref. 13 |
| F852 | — | P(VDF-TrFE) | 5 × 10³ | 10⁴ | −30 V, +20 V | Extrinsically | Ref. 14 |
| | | | | | | stetchable | |

The memory transistor in the embodiment of this invention was confirmed to be the first intrinsically stretchable memory transistor reported, featuring a high memory current ratio (6×10⁵) and significant retention time (10⁶ seconds).

### 4-5. Skin-Type Active Matrix Memory Transistor Array

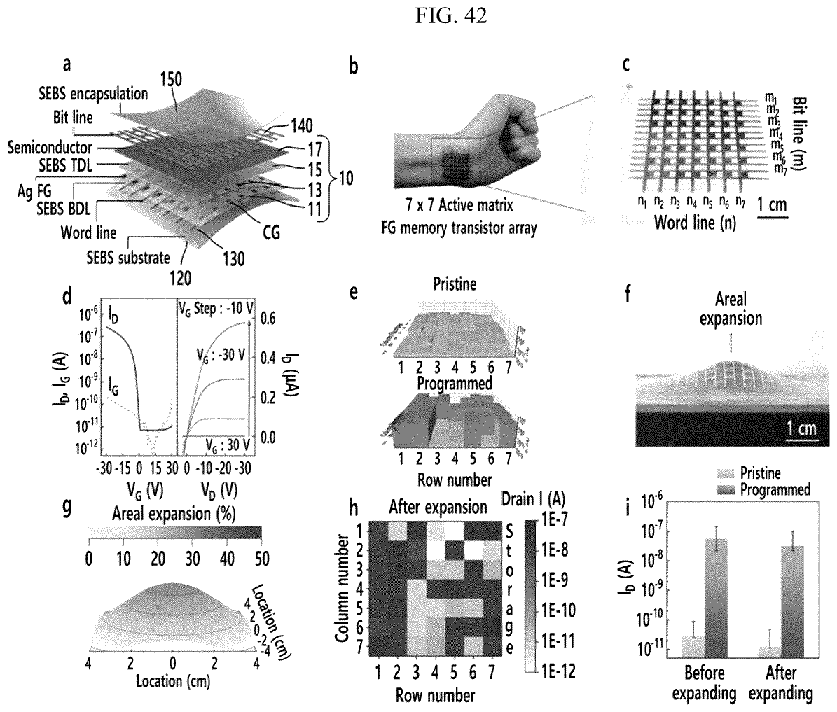

(a) of FIG. 42 is a circuit diagram of the active matrix array.

(b) of FIG. 42 shows a photograph of the array on a human wrist.

(c) of FIG. 42 provides an enlarged image of the active matrix array.

(d) of FIG. 42 presents the transfer (left) and output (right) characteristics of a unit transistor in the active matrix array.

(e) of FIG. 42 maps the drain current of a 7×7 active matrix array in its pristine state (top) and programmed state (bottom).

(f) of FIG. 42 and (g) of FIG. 42 display a photograph and deformation mapping of an area-expanded active matrix array using a ball indenter, respectively.

(h) of FIG. 42 maps the drain current of the 7×7 active matrix array after area expansion.

(i) of FIG. 42 shows a comparison of the drain current before and after area expansion, and before and after programming.

All writing processes in FIG. 42 were performed using a gate voltage of 50 V, light intensity of 10 mW/cm², and 5 seconds of white light exposure. The read drain and gate voltages were set to −10 V and 0 V, respectively.

FIG. 43 illustrates the manufacturing process of a memory device (100) with a stretchable active matrix (7×7) memory transistor array.

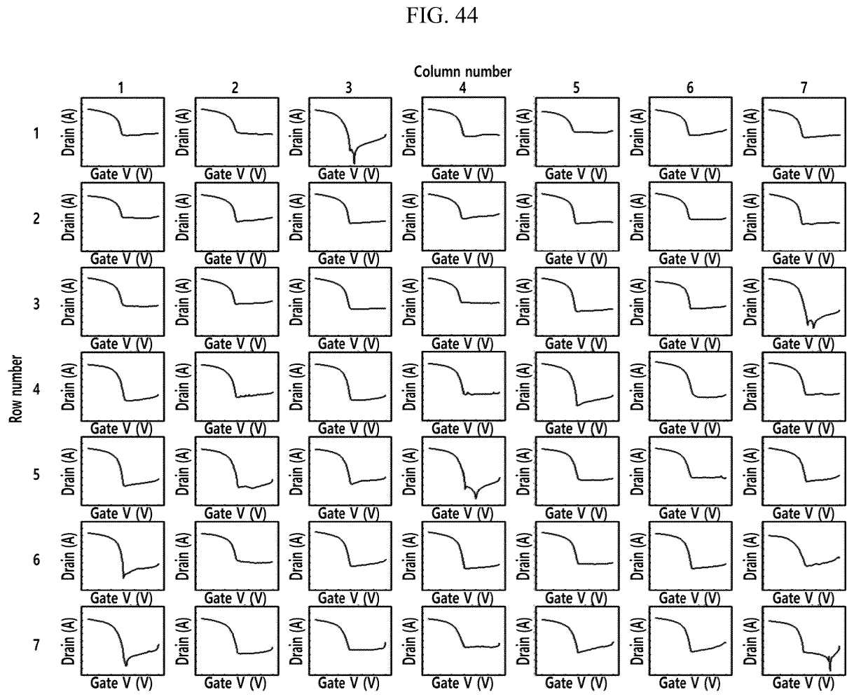

FIG. 44 is a graph showing the transfer characteristics (VD=−10 V) of all unit cells in the pristine active matrix array.

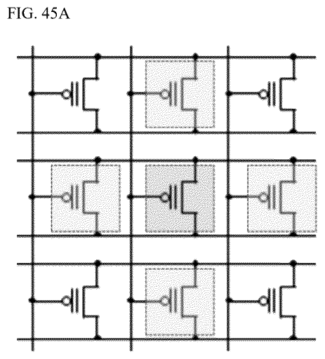

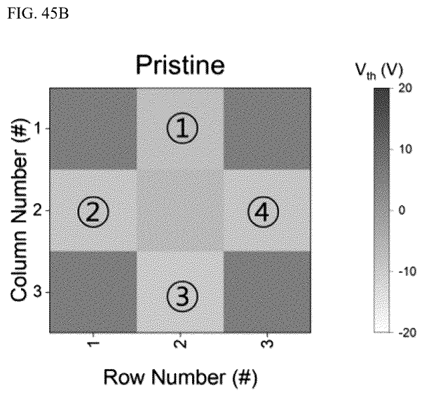

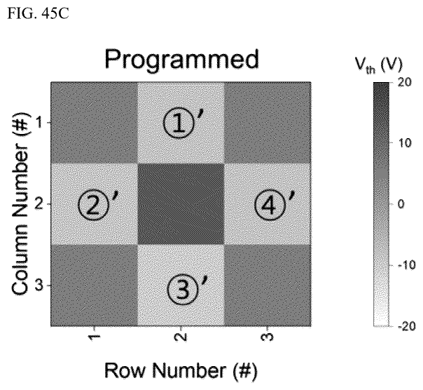

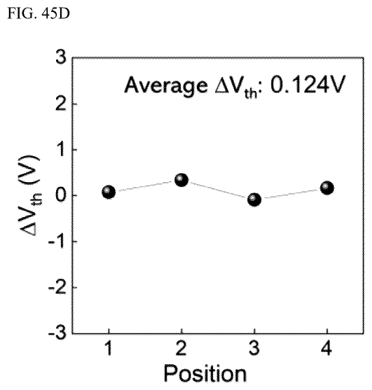

FIG. 45A is a schematic diagram of the selective programming process of the active matrix array (p represents a programmed cell).

FIGS. 45B and 45C are threshold voltage mapping diagrams of the pristine memory transistors and the programmed memory transistors, respectively.

FIG. 45D is a graph showing the threshold voltage shift (ΔVth: Vth #−Vth #′) of memory transistors located around the programmed memory transistors.

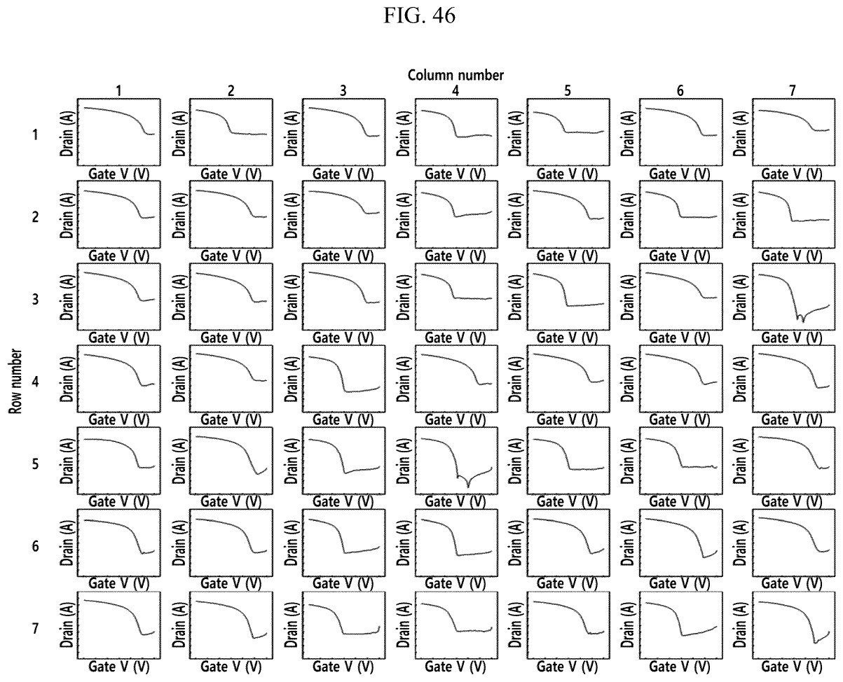

FIG. 46 is a graph showing the transfer characteristics (VD=−10 V) of all unit cells in the programmed active matrix array following an ASCII code pattern spelling the word “Storage.”

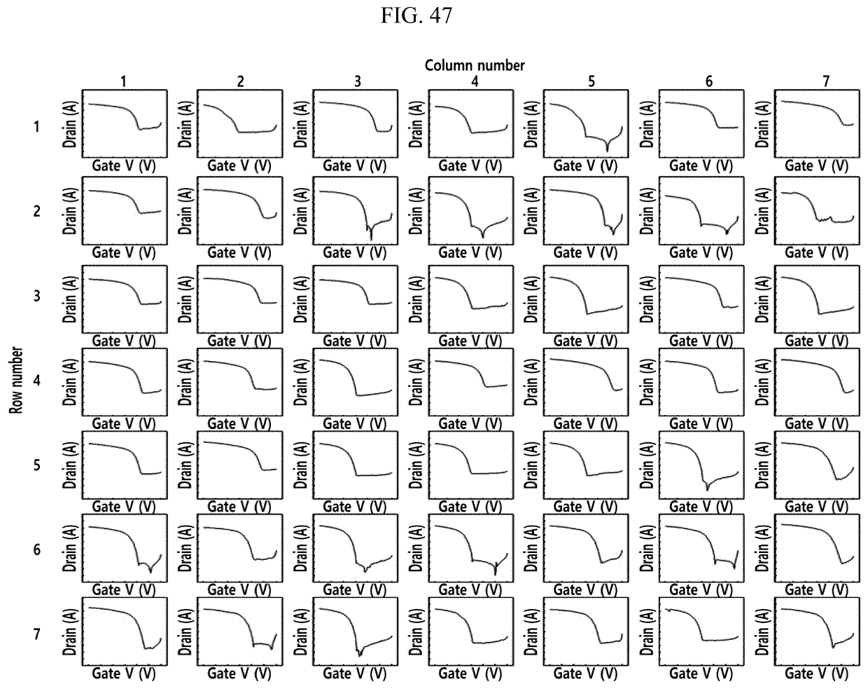

FIG. 47 is a graph showing the transfer characteristics (VD=−10 V) of all unit cells in the programmed active matrix array after ball indentation following the ASCII code for “Storage.”

Finally, to confirm the practical feasibility of integrating stretchable memory transistors, an active matrix FG memory transistor (7×7) array was fabricated to securely store data in 7-bit ASCII (American Standard Code for Information Interchange) code, capable of representing words containing various letters and numbers. The circuit diagram and photographs of the active matrix transistor array are shown in (a-c) of FIG. 42 and FIG. 43.

The transfer and output characteristics of the transistors in the array exhibited typical p-type behavior with low gate leakage current ((d) of FIG. 42).

The pristine ID mapping at Vread and the transfer characteristics of the 49 transistors in the array are shown in (e, top) of FIG. 42 and FIG. 44, respectively. To store information in the array, all pixel devices were programmed using a dual stimulus pattern (light and bias) corresponding to ASCII codes.

Negligible crosstalk was observed, owing to the dual locking system (both optical and electrical stimuli) and the isolation pattern of the Ag FG (FIG. 45). The programmed ID mapping is shown in (e, bottom) of FIG. 42, where each column represents a character spelling the word “Storage” (Table 3 and FIG. 46).

TABLE 3
ASCII Code Table (A-Z and a-z).

| Digital code | Letter | Digital code | Letter |
|---|---|---|---|
| 1000001 | A | 1100001 | a |
| 1000010 | B | 1100010 | b |
| 1000011 | C | 1100011 | c |
| 1000100 | D | 1100100 | d |
| 1000101 | E | 1100101 | e |
| 1000110 | F | 1100110 | f |
| 1000111 | G | 1100111 | g |
| 1001000 | H | 1101000 | h |
| 1001001 | I | 1101001 | i |
| 1001010 | J | 1101010 | j |
| 1001011 | K | 1101011 | k |
| 1001100 | L | 1101100 | l |
| 1001101 | M | 1101101 | m |
| 1001110 | N | 1101110 | n |
| 1001111 | O | 1101111 | o |
| 1010000 | P | 1110000 | p |
| 1010001 | Q | 1110001 | q |
| 1010010 | R | 1110010 | r |
| 1010011 | S | 1110011 | s |
| 1010100 | T | 1110100 | t |
| 1010101 | U | 1110101 | u |
| 1010110 | V | 1110110 | v |
| 1010111 | W | 1110111 | w |
| 1011000 | X | 1111000 | x |
| 1011001 | Y | 1111001 | y |
| 1011010 | Z | 1111010 | z |

Additionally, the information recorded in the active matrix array was preserved even under area expansion of up to 31% using a plastic ball indenter ((f, g) of FIG. 42). The read currents (ID at Vread) in the pristine and programmed states remained nearly unchanged before and after area expansion ((h, i) of FIG. 42 and FIG. 47). This demonstrates the applicability of intrinsically stretchable memory to personalized electronic skin.

The embodiment of the present invention provides an intrinsically stretchable FG memory transistor operating with a dual-mode writing system that utilizes both electrical and optical stimuli to enable dual-lock storage for electronic skin data.

The memory device exhibited a high memory on/off ratio (>10⁵), a wide memory window (17 V), and a long retention time (>10⁶ seconds). These memory performance characteristics were stably maintained under 50% uniaxial or 30% biaxial strain conditions. Moreover, the memory transistor in the embodiment not only demonstrated high mechanical durability over multiple stretching cycles (1,000 cycles) but also exhibited excellent environmental stability against temperature, humidity, air, and peel-off conditions, confirming its suitability for use in e-skin memory devices.

Finally, a 7×7 active matrix memory transistor array capable of storing digitized personal data using ASCII codes was fabricated, and its feasibility for electronic skin applications was validated.

The embodiment of the present invention can be further advanced through the integration of conventional semiconductor processing techniques, such as photolithography, to achieve higher device density and memory capacity.

As described above, although the embodiments have been explained with reference to limited drawings, those skilled in the art will understand that various modifications and variations can be made based on the above descriptions. For example, the described techniques may be performed in a different order than described, and/or the components of the systems, structures, devices, circuits, etc., may be combined or configured differently than described, or substituted or replaced by other components or equivalents while achieving appropriate results.

Therefore, other implementations, variations, and equivalents to the claims are also within the scope of the claims set forth below.

What is claimed is:

1. A memory transistor comprising:
a blocking dielectric layer formed of an elastomer film;
a stretchable floating gate layer laminated on an upper surface of the blocking dielectric layer;
a tunneling dielectric layer formed of an elastomer film, laminated on an upper surface of the blocking dielectric layer and the floating gate layer; and
a nanoweb semiconductor layer laminated on an upper surface of the tunneling dielectric layer,
wherein the stretchable floating gate layer is configured to include metal nanoparticles deposited in particulate form on the tunneling dielectric layer through thermal evaporation to form a stretchable planar structure.

2. The memory transistor of claim 1,
wherein the blocking dielectric layer is configured to be formed by spin-coating an elastomer solution to a thickness of 750 to 900 nm,
wherein the tunneling dielectric layer is configured to be formed by spin-coating an elastomer solution to a thickness of 25 to 100 nm,
wherein the floating gate layer is configured to be formed to a thickness of 1 to 20 nm.
wherein the nanoweb semiconductor layer is configured to be formed by mixing organic semiconductor nanofibers within an elastomer matrix.

3. The memory transistor of claim 2,
wherein the organic semiconductor nanofibers are configured to be formed using DPPT-TT, represented by Chemical Formula 1 as [poly-[2,5-bis(2-octyldodecyl)-3,6-di(thiophen-2-yl)pyrrolo[3,4-c]pyrrole-1,4(2H,5H)-dionel-alt-thieno[3,2-b]thiophene]].

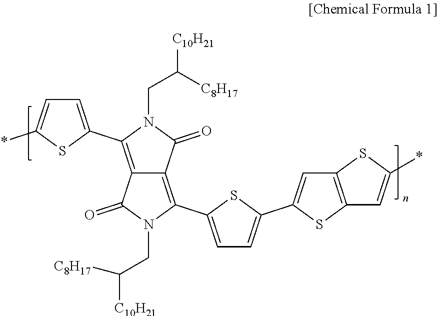

4. The memory transistor of claim 3,
wherein the DPPT-TT has a weight-average molecular weight of 100,000 g/mol or more.

5. The memory transistor of claim 1,
wherein the elastomer is an organic elastomer polymer SEBS (styrene-ethylene-butylene-styrene) represented by Chemical Formula 2.

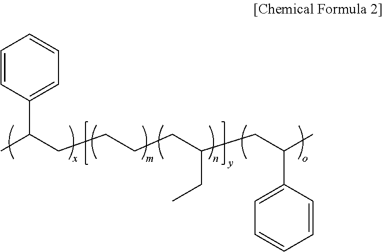

6. The memory transistor of claim 5,
wherein in the SEBS of Chemical Formula 2, the composition ratio of (x+o) to (m+n) is 18:82 to 20:80.

7. The memory transistor of claim 5,
wherein the nanoweb semiconductor layer is a DPPT-TT nanofiber SEBS composite film (DPPT-TT:SEBS composite film) formed by the nano-confinement effect, with a layer of the organic semiconductor nanofibers formed within the SEBS matrix.

8. The memory transistor of claim 7,
wherein the DPPT-TT:SEBS composite film is manufactured by spin-coating a solution in which DPPT-TT, represented by Chemical Formula 1, and SEBS, represented by Chemical Formula 2, are dissolved in a substance of Chemical Formula 3 at a weight ratio of 1-3:7-9 and at a concentration of 0.6-0.8 wt %.

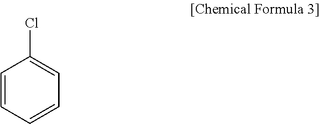

9. The memory transistor of claim 1,
wherein, when writing is performed on the floating gate layer using a write voltage and light, the memory transistor operates as a flash memory or a WORM (Write Once Read Many) memory depending on the thickness of the floating gate layer.

10. The memory transistor of claim 9,
wherein, when writing is performed by applying a write voltage and light, the memory transistor operates as a flash memory when the thickness of the floating gate layer is 15 to 20 nm.

11. The memory transistor of claim 10,
wherein, when writing is performed by applying a write voltage and light, the memory transistor operates as a WORM (Write Once Read Many) memory when the thickness of the floating gate layer is 1 to 10 nm.

12. The memory transistor of claim 1, wherein the memory transistor further comprises:
a control gate layer configured to be formed on a lower surface of the blocking dielectric layer, wherein metal nanoparticles are deposited in particulate form through thermal evaporation to provide stretchability;
a stretchable protective layer configured to be laminated on an upper surface of the tunneling dielectric layer; and
an electrode layer configured to include a source electrode layer and a drain electrode layer, spaced apart from each other and formed on an upper surface of the stretchable protective layer to create a channel in the nanoweb semiconductor layer.

13. The memory transistor of claim 12,
wherein the control gate layer is configured to be formed to a thickness of 40 to 60 nm.

14. A method for manufacturing a memory transistor, the method comprising:
forming a control gate layer and a substrate laminate by depositing metal nanoparticles in particulate form on a stretchable substrate through thermal evaporation to create a stretchable planar structure;
forming a floating gate layer and a tunneling dielectric layer laminate by laminating a floating gate layer, wherein metal nanoparticles are deposited in particulate form on a stretchable tunneling dielectric layer through thermal evaporation to create a stretchable planar structure;
forming a stretchable blocking dielectric layer on a surface of the control gate layer of the control gate layer and substrate laminate;
transferring the floating gate layer and tunneling dielectric layer laminate onto a surface of the blocking dielectric layer of the control gate layer and substrate laminate so that the floating gate layer is bonded to the blocking dielectric layer; and
transferring a nanoweb semiconductor layer onto a surface of the tunneling dielectric layer of the floating gate layer and tunneling dielectric layer laminate.

15. A memory device comprising:
a stretchable substrate;
one or more wordlines configured to be spaced apart and arranged along a first direction on an upper surface of the stretchable substrate;
an active layer configured to be laminated on the stretchable substrate and the one or more wordlines, the active layer including one or more stretchable floating gate layers configured to be spaced apart in a lattice arrangement;
one or more bitlines configured to be spaced apart and arranged along a second direction perpendicular to the first direction on an upper surface of the active layer; and
a stretchable protective layer configured to be laminated on the active layer and the one or more bitlines,
wherein the stretchable floating gate layer is configured to include metal nanoparticles deposited in particulate form on a tunneling dielectric layer through thermal evaporation to form a stretchable planar structure.

16. The memory device of claim 15,
wherein the active layer is configured to comprise:
a blocking dielectric layer configured to be formed of an elastomer film and laminated on the stretchable substrate and the one or more wordlines;
a stretchable floating gate layer configured to be laminated on the blocking dielectric layer at the intersection regions of the wordlines and bitlines;
a tunneling dielectric layer configured to be formed of an elastomer film and laminated on the blocking dielectric layer and the floating gate layer; and
a nanoweb semiconductor layer configured to be laminated on the tunneling dielectric layer.

17. The memory device of claim 15,
wherein the active layer is configured to operate as an active layer of a flash memory or an active layer of a WORM (Write Once Read Many) memory depending on the thickness of the floating gate layer when writing is performed using a write voltage and light.

18. The memory device of claim 17,
wherein the active layer is configured to operate as an active layer of a flash memory when the thickness of the floating gate layer is 15 to 25 nm and writing is performed by applying a write voltage and light.

19. The memory device of claim 17,
wherein the active layer is configured to operate as an active layer of a WORM (Write Once Read Many) memory when the thickness of the floating gate layer is 1 to 10 nm and writing is performed by applying a write voltage and light.
